(19) United States
(12) Patent Application Publication
(10) Pub. No.: US 2024/0250177 A1
(43) Pub. Date: Jul. 25, 2024

(54) METAL OXIDE THIN FILM TRANSISTOR AND DISPLAY PANEL

(71) Applicant: BOE TECHNOLOGY GROUP CO., LTD., Beijing (CN)

(72) Inventors: Dapeng XUE, Beijing (CN); Lizhong WANG, Beijing (CN); Shuilang DONG, Beijing (CN); Hehe HU, Beijing (CN); Nianqi YAO, Beijing (CN); Guangcai YUAN, Beijing (CN); Ce NING, Beijing (CN); Zhengliang LI, Beijing (CN); Dongfang WANG, Beijing (CN); Liping LEI, Beijing (CN); Chen XU, Beijing (CN); Jie HUANG, Beijing (CN)

(73) Assignee: BOE TECHNOLOGY GROUP CO., LTD., Beijing (CN)

(21) Appl. No.: 18/014,269

(22) PCT Filed: Mar. 31, 2022
(86) PCT No.: PCT/CN2022/084443

§ 371 Date: Jan. 3, 2023

(51) Int. Cl. H01L 29/786; H01L 27/12; H01L 29/417

(52) U.S. Cl. CPC H01L 29/7869; H01L 27/1225; H01L 29/41733; H01L 29/78696

(57) ABSTRACT

A metal oxide thin film transistor is provided, which includes a metal oxide semiconductor layer, including a first semiconductor layer and a second semiconductor layer, the carrier mobility of the first semiconductor layer is higher than that of the second semiconductor layer; the metal oxide semiconductor layer includes a lower surface, an upper surface and a lateral surface, the source electrode is in contact with the lateral surface and the upper surface; the region where the lateral surface contacts the source electrode or the drain electrode includes a first contact region and a second contact region; which have the shape: a first angle between the lower surface of the metal oxide semiconductor layer and the lateral surface of the first contact region is larger than a second angle between the lower surface of the metal oxide semiconductor layer and the lateral surface of the second contact region.

### TECHNICAL FIELD

The embodiments of the present disclosure relate to a metal oxide thin film transistor and a display panel.

### BACKGROUND

Among the metal oxide semiconductor devices, metal oxide semiconductor (MOS)-thin film transistor (TFT) has attracted wide attention from research institutions and industry. Compared with amorphous silicon (a-Si) semiconductor thin film transistor, MOS-TFT has many advantages, such as low leakage current, high mobility (10-100 times that of a-Si), transparency to visible light, capability of manufacturing large-area high-quality thin film layers at lower temperature compared with low-temperature polysilicon TFT, easy compatibility with the current production equipment of a-Si production line, and convenience in manufacturing on flexible substrates. Metal oxide semiconductor thin film transistors have been commercialized in the display field for many years. However, there is still a need for continuous optimization in at least the following aspects, such as improving yield and TFT characteristics.

### SUMMARY

The embodiment of the present disclosure provides a metal oxide thin film transistor, which conmprises a metal oxide semiconductor layer on a base substrate, and a source electrode and a drain electrode being in contact with the metal oxide semiconductor layer; the metal oxide semiconductor layer comprises a stacked structure, the stacked structure at least comprises a first semiconductor layer and a second semiconductor layer, a carrier mobility of the first semiconductor layer is higher than a carrier mobility of the second semiconductor layer; the metal oxide semiconductor layer comprises a lower surface, an upper surface and a lateral surface, and the source electrode is in contact with the lateral surface and the upper surface; a region of the lateral surface being in contact with the source electrode or the drain electrode at least comprises a first contact region located on the first semiconductor layer and a second contact region located on the second semiconductor layer; the first contact region and the second contact region on the oxide semiconductor layer comprise a shape provided in the following: the shape comprises a first angle between the lower surface of the metal oxide semiconductor layer and the lateral surface of the first contact region, and a second angle between the lower surface of the metal oxide semiconductor layer and the lateral surface of the second contact region, and the first angle is larger than the second angle.

In one embodiment, the first angle is an included angle between at least a portion of the region of the first contact region and a flat surface parallel to the lower surface and intersecting with the first contact region; and the second angle is an included angle between at least a portion of the region of the second contact region and a flat surface parallel to the lower surface and intersecting with the second contact region.

In one embodiment, the second semiconductor layer is close to the source electrode and the drain electrode in the stacked structure of the metal oxide semiconductor layer; the first contact region is all or part of a contact region between the source electrode or the drain electrode and the first semiconductor layer, and the second contact region is all or part of a contact region between the source electrode or the drain electrode and the second semiconductor layer.

In one embodiment, the first semiconductor layer and the second semiconductor layer satisfy at least one of the following conditions: the first semiconductor layer and the second semiconductor layer comprise metal oxide semiconductors with different crystallinity; the first semiconductor layer and the second semiconductor layer comprise metal oxide semiconductors with different compositions; the first semiconductor layer and the second semiconductor layer comprise metal oxide semiconductors with different band gaps.

In one embodiment, a crystallinity of the metal oxide of the first semiconductor layer is smaller than a crystallinity of the metal oxide of the second semiconductor layer.

In one embodiment, in a direction perpendicular to a main surface of the base substrate, an extension distance of the first contact region from a position closest to the upper surface to a position closest to the lower surface is smaller than an extension distance of the second contact region from a position closest to the upper surface to a position closest to the lower surface.

In one embodiment, a width of an projection contour of the first contact region on the base substrate is L1, a width of an projection contour of the second contact region on the base substrate is L2, and L1 is less than L2.

In one embodiment, the L2 is 2 to 5 times that of the L1.

In one embodiment, L2 ranges from 2 nm to 50 nm and L1 ranges from 0.1 nm to 5 nm.

In one embodiment, the metal oxide semiconductor layer further comprises a third semiconductor layer; the third semiconductor layer is located between the first semiconductor layer and the second semiconductor layer and is in direct contact with the first semiconductor layer and the second semiconductor layer.

In one embodiment, a crystallinity of at least a part of the metal oxide semiconductor layer satisfies: a crystallinity of the metal oxide of the third semiconductor layer is larger than a crystallinity of the metal oxide of the first semiconductor layer and smaller than a crystallinity of the metal oxide of the second semiconductor layer.

In one embodiment, a carrier concentration of at least a part of the metal oxide semiconductor layer satisfies: a carrier concentration of the third semiconductor layer is smaller than a carrier concentration of the first semiconductor layer.

In one embodiment, the metal oxide semiconductor layer comprises an overlapping region that at least partially overlaps with a projection of the source electrode or the drain electrode on the base substrate, and a non-overlapping region that does not overlap with the projection of the source electrode or the drain electrode on the base substrate; a content percentage of oxygen (O) element of the overlapping region is smaller than a content percentage of oxygen element of the non-overlapping region.

In one embodiment, a difference between the content percentage of oxygen element of the non-overlapping region and the content percentage of oxygen element of the overlapping region is not less than 10%.

In one embodiment, the difference between the content percentage of oxygen element of the non-overlapping region and the content percentage of oxygen element of the overlapping region is in a range from 10% to 30%.

In one embodiment, the content percentage of oxygen element of the non-overlapping region is in a range from 38% to 58%; the content percentage of oxygen element of the overlapping region is in a range from 20% to 40%.

In one embodiment, at least a part of the non-overlapping region and the overlapping region comprise nitrogen (N) element, and a content percentage of nitrogen element of the overlapping region is smaller than a content percentage of nitrogen element of the non-overlapping region.

In one embodiment, the content percentage of nitrogen element of the overlapping region is between 3% and 10%, and the content percentage of nitrogen element of the non-overlapping region is between 5% and 15%.

In one embodiment, both the non-overlapping region and the overlapping region comprise metal In (indium) element and Zn (zinc) element, a difference between a content percentage of In element and a content percentage of Zn element in the overlapping region is smaller than a difference between a content percentage of In element and a content percentage of Zn element in the non-overlapping region, and the content percentage of In element in the non-overlapping region is larger than the content percentage of Zn element in the non-overlapping region.

In one embodiment, both the non-overlapping region and the overlapping region comprise metal element In, and a content percentage of In element of the overlapping region is greater than a content percentage of In element of the non-overlapping region.

In one embodiment, the content percentage of In element of the overlapping region is between 15% and 20%; the content percentage of In element of the non-overlapping region is between 8% and 15%.

In one embodiment, the first contact region is a first concave surface, and the first concave surface is only located in the first semiconductor layer.

In one embodiment, in a direction of the first concave surface away from the lower surface, the first angle first increases and then decreases, and a distance between the first concave surface and a center of the metal oxide semiconductor layer first decreases and then increases.

In one embodiment, in a direction of the first concave surface away from the lower surface, the first angle is a constant value, or in the direction of the first concave surface away from the lower surface, the first angle gradually increases, and the position with the largest first angle is adjacent to the second contact region.

In one embodiment, the first contact region is the first concave surface, and values of the first angles between different positions of the first contact region and the lower surface are the same value or a plurality of different values; the second contact region is a smooth second flat surface, and second angles between different positions of the second contact region and a flat surface parallel to at least a part of the lower surface and intersecting with the second contact region have the same value or a plurality of different values.

In one embodiment, a corner is formed between the first contact region and the second contact region, and an included angle between two surfaces corresponding to the corner is an obtuse angle.

In one embodiment, a contour of the metal oxide semiconductor layer comprises four edges, and the four edges correspond to a first lateral surface, a second lateral surface, a third lateral surface and a fourth lateral surface respectively, and the first lateral surface and the second lateral surface are oppositely arranged, the third lateral surface and the fourth lateral surface are oppositely arranged; the first lateral surface, the third lateral surface, the second lateral surface and the fourth lateral surface are sequentially arranged; the first contact region is a region where the source electrode is in contact with at least one of the second lateral surface and the third lateral surface.

In one embodiment, at least one of the first lateral surface, the third lateral surface, the second lateral surface and the fourth lateral surface satisfies a shape provided in the following: the shape comprises a third angle formed between the lateral surface and the lower surface of the first semiconductor layer of the metal oxide semiconductor layer and a fourth angle formed between the lateral surface and the lower surface of the second semiconductor layer of the metal oxide semiconductor layer.

In one embodiment, in the second semiconductor layer, the fourth angle in the first lateral surface is smaller than the fourth angle in the second lateral surface.

In one embodiment, in the second semiconductor layer, the fourth angle of the third lateral surface is larger than the fourth angle of the fourth lateral surface.

In one embodiment, in the second semiconductor layer, the fourth angle of the second lateral surface is larger than the fourth angle of the third lateral surface.

In one embodiment, the third angle of the first lateral surface is smaller than the third angle of the second lateral surface.

In one embodiment, the third angle of the fourth Jateral surface is smaller than the third angle of the third lateral surface.

In one embodiment, among the third angle on the first lateral surface, the third angle on the second lateral surface, the third angle on the third lateral surface and the third angle on the fourth lateral surface, the third angle on the second lateral surface is the largest and the third angle on the fourth lateral surface is the smallest.

In one embodiment, the first contact region and the second contact region are located on the third lateral surface or the fourth lateral surface.

In one embodiment, the metal oxide thin film transistor is a switching transistor of a pixel display region, and the metal oxide thin film transistor is arranged in a pixel region defined by a gate line and a data line which intersect with each other, the gate line and the data line respectively extend along a row direction and a column direction of a pixel array, the metal oxide semiconductor layer extends along the direction of the gate line, and the first contact region and the second contact region are respectively located at two ends of the extension direction of the metal oxide semiconductor layer.

In one embodiment, the first semiconductor layer comprises an amorphous or nano-crystalline metal oxide semiconductor; and the second semiconductor layer comprises a c-axis crystallized metal oxide semiconductor.

In one embodiment, a thickness of the second semiconductor layer is greater than a thickness of the first semiconductor layer, the thickness of the first semiconductor layer is 5 nm to 20 nm, and the thickness of the second semiconductor layer is 20 nm to 100 nm.

In one embodiment, the metal oxide semiconductor layer comprises indium element, gallium element and zinc element, and an element distribution in at least a part of the region of the metal oxide semiconductor layer satisfies the following requirements: a molar ratio of zinc element to indium element is (2-4):(3-5), and a molar ratio of zine element to gallium element is (2-4):(1-2).

In one embodiment, the metal oxide semiconductor layer comprises an amorphous layer or nano-crystalline layer, a crystalline layer, and a transition layer with a crystalline state between the amorphous layer or nano-crystalline layer and the crystalline layer, and the transition layer is located between the amorphous layer or nano-crystalline layer and the crystalline layer in a thickness direction of the metal oxide semiconductor layer; a molar ratio of indium element in the amorphous layer or nano-crystalline layer to indium element in the crystalline layer is 0.97-1.38, and a molar ratio of indium element in the amorphous layer or nano-crystalline layer to indium element in the transition layer is 1.36-1.64; a molar ratio of gallium element in the amorphous layer or nano-crystalline layer to gallium element in the crystalline layer is 0.57-0.92, and a molar ratio of gallium element in the amorphous layer or nano-crystalline layer to gallium element in the transition layer is 0.5-1.1; a molar ratio of zinc element in the amorphous layer or nano-crystalline layer to zinc element in the crystalline layer is 0.8-0.96, and a molar ratio of zinc element in the amorphous layer or nano-crystalline layer to zinc element in the transition layer is 0.74-0.83.

In one embodiment, a ratio of a thickness of the second semiconductor layer to a thickness of the first semiconductor layer ranges from 0.2 to 5.

In one embodiment, the metal oxide semiconductor layer further comprises a third semiconductor layer; the third semiconductor layer is located between the first semiconductor layer and the second semiconductor layer and in direct contact with the first semiconductor layer and the second semiconductor layer; a ratio of a thickness of the third semiconductor layer to a thickness of the first semiconductor layer is between 0.25 and 0.75.

In one embodiment, the thickness of the first semiconductor layer is between 5 nm and 20 nm, and the thickness of the third semiconductor layer is between 1 nm and 6 nm.

The embodiment of the present disclosure further provides a display panel, and the display panel comprises any one of the metal oxide thin film transistors mentioned above.

### BRIEF DESCRIPTION OF THE DRAWINGS

In order to more clearly explain the technical solution of the embodiments of the present disclosure, the following will briefly introduce the drawings of the embodiments. Obviously, the drawings in the following description only relate to some embodiments of the present disclosure, but not limit the present disclosure.

FIG. 1A is a schematic cross-sectional structure diagram of a metal oxide thin film transistor provided by at least one embodiment of the present disclosure;

FIG. 1B is a schematic cross-sectional structure diagram of a metal oxide thin film transistor provided by at least one embodiment of the present disclosure;

FIG. 1C is a schematic cross-sectional structure diagram of a partial stacked structure of a semiconductor layer of a metal oxide thin film transistor provided by at least one embodiment of the present disclosure;

FIG. 1D is a schematic cross-sectional structure diagram of a partial stacked structure of a semiconductor layer of a metal oxide thin film transistor provided by at least one embodiment of the present disclosure;

FIG. 1E is a schematic cross-sectional structure diagram of a partial stacked structure of a semiconductor layer of a metal oxide thin film transistor provided by at least one embodiment of the present disclosure;

Fig. 1F is a schematic cross-sectional structure diagram of a partial stacked structure of a semiconductor layer of a metal oxide thin film transistor provided by at least one embodiment of the present disclosure;

FIG. 2 is a schematic planar structure diagram of orthographic projections A-A′ and B-B′ of lateral edges of a first contact region adjacent to a lower surface and a second contact region on the base substrate respectively, and an orthographic projection C-C′ of a lateral edge of the second contact region adjacent to an upper surface on the base substrate provided by an embodiment of the present disclosure;

FIG. 3 is a schematic cross-sectional structure diagram of another metal oxide thin film transistor provided by at least one embodiment of the present disclosure;

FIG. 4 is a schematic cross-sectional structure diagram of another metal oxide thin film transistor provided by at least one embodiment of the present disclosure;

FIG. 5 is a transmission electron microscope scanning schematic diagram of a cross-sectional structure of a metal oxide thin film transistor provided by at least one embodiment of the present disclosure;

FIG. 6 is a transmission electron microscope scanning schematic diagram of a cross-sectional structure of an upper surface of a metal oxide semiconductor layer provided by at least one embodiment of the present disclosure;

FIG. 7 is a transmission electron microscope scanning schematic diagram of a cross-sectional structure of a lower surface of a metal oxide semiconductor layer provided by at least one embodiment of the present disclosure;

FIG. 8 is a schematic cross-sectional structure diagram of another metal oxide thin film transistor provided by at least one embodiment of the present disclosure;

FIG. 9 is a schematic cross-sectional structure of a curved surface in FIG. 8 from the outside to the inside perpendicular to the paper surface;

FIG. 10 is a transmission electron microscope scanning schematic diagram of a cross-sectional structure of another metal oxide thin film transistor provided by at least one embodiment of the present disclosure;

FIG. 11 is a schematic cross-sectional structure diagram of another metal oxide thin film transistor provided by at least one embodiment of the present disclosure;

FIG. 12 is a schematic plan view of a pixel unit according to at least one embodiment of the present disclosure;

FIG. 13 is a schematic cross-sectional structure of the metal oxide thin film transistor in the structure shown in FIG. 12, cut along a line parallel to a first direction C-C′; and

FIG. 14 is a schematic cross-sectional structure of the metal oxide thin film transistor in the structure shown in FIG. 12, cut along a line parallel to a second direction E-E′.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

In a metal oxide thin film transistor, the morphology of a lateral surface of a metal oxide semiconductor layer has certain influence on the characteristics of the metal oxide thin film transistor.

At present, the metal oxide semiconductor layer with a stacked structure is a way to improve the mobility of TFT (thin film transistor). However, due to the different film quality of a stacked metal oxide semiconductor layer, when the stacked metal oxide semiconductor layer is etched by an etching solution, different shapes are often etched, so that a lateral surface of the semiconductor layer is exposed to the outside and directly contacts with a source electrode or a drain electrode, which may lead to the contamination of lateral impurities to the film layer which is convenient for carrier transmission, which is not conducive to the improvement of TFT characteristics.

The present application provides a TFT, which can effectively improve the TFT characteristics. The TFT of the present application will be explained by different embodiments below.

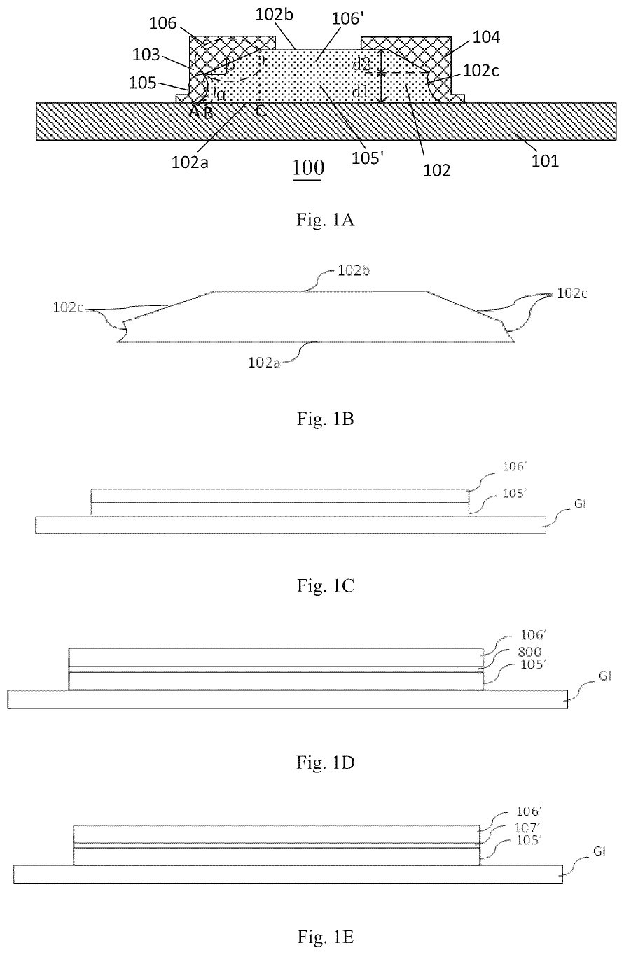

As illustrated by FIGS. 1A to 1F and FIGS. 2 to 3, at least one embodiment of the present disclosure provides a metal oxide thin film transistor, which includes:
A metal oxide semiconductor layer 102 arranged on a base substrate 101, and a source electrode 103 and a drain electrode 104 being in contact with the metal oxide semiconductor layer 102.

The metal oxide semiconductor layer 102 has a stacked structure, the stacked structure at least includes a first semiconductor layer 105′ and a second semiconductor layer 106′, and the carrier mobility of the first semiconductor layer 105′ is higher than that of the second semiconductor layer 106′.

FIG. 1B is a schematic longitudinal cross-sectional diagram of the metal oxide semiconductor, as illustrated by FIG. 1B, the metal oxide semiconductor layer 102 includes a lower surface 102a, an upper surface 102b and a lateral surface 102c.

As illustrated by FIGS. 1A and 1B, the source electrode 103 is in contact with the lateral surface 102c and the upper surface 102b; a region of the lateral surface 102c in contact with the source electrode or the drain electrode at least includes a first contact region on the first semiconductor layer and a second contact region on the second semiconductor layer.

As illustrated by FIG. 1A, the first contact region and the second contact region on the oxide semiconductor layer 102 have a shape provided in the following: the shape includes a first angle between the lower surface of the metal oxide semiconductor layer and the lateral surface of the first contact region, and a second angle between the lower surface of the metal oxide semiconductor layer and the lateral surface of the second contact region; and the first angle is larger than the second angle.

In the above-mentioned embodiment, the metal oxide semiconductor layer 102 is in direct contact with the source electrode 103 and the drain electrode 104. Specifically, the source electrode 103 and the drain electrode 104 are spaced apart and insulated from each other. One side of the source electrode 103 and the drain electrode 104 is in direct contact with the metal oxide semiconductor layer 102, and the other side of the source electrode 103 and the drain electrode 104 is in direct contact with an insulating layer (such as a passivation layer PVX). The source electrode 103 and the drain electrode 104 located between the metal oxide semiconductor layer 102 and the insulating layer each includes at least one main conductive layer, such as copper, aluminum or alloy of copper and aluminum. In some embodiments, the source electrode 103 and the drain electrode 104 are further provided with other film layers above or below the main conductive layer. For example, the surfaces of the source electrode 103 and the drain electrode 104, which are close to the metal oxide semiconductor layer 102, are further provided with a buffer layer, which is a conductive film layer. The conductive film layer may be an oxide film layer of the main conductive layer or other types of metals or alloys, and the buffer layer may have a certain metal ion blocking effect or a blocking effect of hydrogen element or oxygen element, so as to prevent the main conductive layer from being oxidized or seriously oxidized, or to prevent the diffusion or excessive diffusion of metal ions to the metal oxide semiconductor layer, thereby resulting in the semiconductor characteristics of the metal oxide semiconductor layer being affected. Illustratively, the source electrode 103 and the drain electrode 104 have a double-layer structure, including a copper layer and a molybdenum-niobium alloy layer, and the molybdenum-niobium alloy layer is in direct contact with the metal oxide semiconductor layer 102. The side of the main conductive layer away from the metal oxide semiconductor layer can also be provided with a buffer layer, which can be a conductive layer or a non-conductive layer, a metal oxide or a metal alloy, or an inorganic insulating layer.

In the above-mentioned embodiment, the stacked structure at least includes the first semiconductor layer 105′ and the second semiconductor layer 106′. The carrier mobility of the first semiconductor layer 105′ of the stacked structure is higher than that of the second semiconductor layer 106′. In practice, the first semiconductor layer 105′ and the second semiconductor layer 106′ are sequentially formed by one target under different process conditions, or sequentially formed by different target materials. If the target materials are the same but the process conditions are different, the film quality is different; if the target materials are different, the film materials are different. The first semiconductor layer 105′ and the second semiconductor layer 106′ can be distinguished by determining the quality or material of different film layers by a method provided as follows.

The method respectively comprises the following embodiments:

In some embodiments, by testing the carrier mobility of positions with different thicknesses of metal oxide semiconductor, it is determined that the positions with obvious difference in carrier mobility belong to different film layers, a film layer with the highest carrier mobility is the first semiconductor layer 105′, and a film layer in other film layers, which is located above the first semiconductor layer 105′ and in contact with the source electrode and the drain electrode, is the second semiconductor layer 106′.

In some embodiments, by testing the element composition and oxygen content percentage of positions with different thicknesses of metal oxide semiconductor, if the element type is the same, but the oxygen content percentage is obviously different in the region just below the region between the source electrode and the drain electrode, and obvious stratification is determined by optical photographs, it can be determined that the film layer with higher oxygen content may be the second semiconductor layer 106′, and the film layer with lower oxygen content may be the first semiconductor layer.

In some embodiments, by testing the electron microscope photo of the metal oxide semiconductor, if the photo is obviously layered, for example, divided into two layers, the film layer close to the source electrode and the drain electrode is the second semiconductor layer, and the film layer away from the source electrode and the drain electrode is the first semiconductor layer.

The first semiconductor layer and the second semiconductor layer are film layers formed by two different process conditions or different target materials from a macroscopic point of view, and do not include a thin transition layer that is naturally formed after the two film layers are formed.

In the above-mentioned embodiment, the metal oxide semiconductor layer 102 includes a lower surface 102a, an upper surface 102b, and a lateral surface 102c, which refers to the surfaces of the entire film layer of the metal oxide semiconductor layer 102. If the TFT has a bottom gate structure, the upper surface 102b and the lateral surface 102c are the surfaces that contact the source electrode and the drain electrode, and the lower surface 102a is the surface that contacts the insulating layer. Exemplary, the metal oxide semiconductor layer 102 has a stacked structure, which only includes the first semiconductor layer 105′ and the second semiconductor layer 106′, so that the lower surface of the first semiconductor layer 105′ is the lower surface 102a of the metal oxide semiconductor layer 102, and the upper surface of the second semiconductor layer 106′ is the upper surface 102b of the metal oxide semiconductor layer 102, lateral surfaces of the first semiconductor layer 105′ and the second semiconductor layer 106′ are the lateral surfaces of the metal oxide semiconductor layer 102.

In the above-mentioned embodiment, once the first semiconductor layer and the second semiconductor layer are determined, their respective lateral surfaces are also determined. In the above-mentioned embodiment, a region on the lateral surface being in contact with the source electrode or the drain electrode at least includes the first contact region located on the first semiconductor layer and the second contact region located on the second semiconductor layer.

In the case where the first contact region and the second contact region are determined in the above-mentioned embodiment, if the slope angle (i.e., the above-mentioned first angle) of at least a layout region on the lateral surface of the first semiconductor layer is larger than the slope angle (i.e., the above-mentioned second angle) of at least a layout region on the lateral surface of the second semiconductor layer in any regions satisfying the contact with the source electrode and the drain electrode on the semiconductor layer, it can be considered that the partial region on the lateral surface of the first semiconductor layer is the first contact region, and the at least partial region on the lateral surface of the second semiconductor layer is the second contact region. The first angle is larger than the second angle, so that the area of the lateral surface of the film layer with higher carrier mobility is as small as possible, and the defects in the lateral channel region are as small as possible.

The above-mentioned first contact region and second contact region can also be explained as follows. Taking the source electrode as an example, in a semiconductor region being in contact with the source electrode, as long as there is a slope angle of a lateral surface of a film layer close to the source electrode being smaller than a slope angle of a lateral surface of a film layer away from the source electrode, then the lateral surface of the film layer close to the source electrode is the first contact region, and the lateral surface of the film layer away from the source electrode is the second contact region.

It should be noted that the first contact region and the second contact region are intended to emphasize the existence of such a partial or entire region on the lateral surface of a contact region of the source electrode or the drain electrode, rather than specifically limiting the size and position of the contact region. Any regions in contact with the source electrode or the drain electrode on the semiconductor layer is within the scope of protection of the present application as long as the lateral surface of the second semiconductor and the lateral surface of the first semiconductor side respectively include a second partial region and a first partial region, and the slope angle of the first partial region is larger than that of the second partial region.

In the above-mentioned embodiment, the first contact region is located on the lateral surface of the first semiconductor layer, and the second contact region is located on the lateral surface of the second semiconductor layer.

Taking the source electrode as an example, the first semiconductor layer has a stereoscopic structure with a longitudinally extending lateral surface and a circumferentially extending lateral surface. The longitudinal extension extends along a direction from the second semiconductor layer to the base substrate, and the circumferential extension extends sequentially around the lateral surfaces of the metal oxide semiconductor layer, that is, around the center of the metal oxide semiconductor layer.

In the case where the first semiconductor layer is in contact with the source electrode, the first semiconductor layer includes a longitudinally extending portion and a circumferentially extending portion, and the circumferentially extending portion can be one lateral surface, or two or more lateral surfaces.

The first contact region where the source electrode being in contact with the first semiconductor layer can be explained in the following different embodiments:

In some embodiments, the first contact region may be a part or all of all contact regions of the first semiconductor layer being in contact with the source electrode. Similarly, the second contact region may be a part or all of all contact regions of the second semiconductor layer being in contact with the source electrode.

If the first contact region is a part of all the contact regions being contact with the source electrode, the first contact region may be all longitudinally extending region of the circumferentially extending region, or a part of the longitudinally extending region.

In practical application, a longitudinal cross-sectional view of the TFT including the metal oxide semiconductor layer 102 and the source electrode 103 can be obtained, a longitudinally extending contact region can be determined from the longitudinal cross-sectional view, and a part or all of the longitudinally extending contact region can be selected as the first contact region. Similarly, for the second contact region, a part or all of the longitudinally extending contact region can be selected as the second contact region. For example, in the longitudinal cross-sectional view of the TFT including the metal oxide semiconductor layer 102 and the source electrode 103, if a region in which more than 50% of the region has the first angle larger than the second angle in the curve formed after contacting with the first semiconductor layer, and the region can be determined as the first contact region. Or, a part of the contact region close to the second semiconductor layer is selected as the first contact region.

After the first contact region and the second contact region are determined, it is determined that a first angle is formed between the lower surface of the metal oxide semiconductor layer and the lateral surface of the first contact region, and a second angle is formed between the lower surface of the metal oxide semiconductor layer and the lateral surface of the second contact region.

Upon the first angle and the second angle being determined, according to the different shapes of the first contact region and the second contact region, the test embodiment also includes the following embodiments.

Taking the first contact region as an example, it will be explained by the following different embodiments.

If the edge line in the longitudinal cross-sectional view of the first contact region is almost straight or similar to a straight line as a whole, the first angle may be an included angle between the straight line and the lower surface of the metal oxide semiconductor layer.

If the edge line in the longitudinal cross-sectional view of the first contact region is almost a broken line including at least two line segments, the first angle may be an average value or the minimum value of the included angles between the line segments and the lower surface of the metal oxide semiconductor layer.

If the edge line in the longitudinal cross-sectional view of the first contact region is a curve with a certain radian, the first angle can be an average value or the minimum value of the included angle between line segments, which are formed by connecting different positions, and the lower surface of the metal oxide semiconductor layer. The connection line of different positions can be a connection line between an upper end and a lower end of the first contact region, or a connection lines between any two adjacent points of the upper end and the lower end of the first contact region and a position closed to the center, or a connection line between any adjacent two points of a plurality of points including at least one end or not. In each embodiment, a connection line is a line segment, and the included angle between the line segment and the lower surface of the metal oxide semiconductor layer forms an angle.

If the edge line in the longitudinal cross-sectional view of the first contact region is a curve with more than one curvature center, the first angle may be an average value or the minimum value of the included angles between the line segments, which are formed by connection lines of different positions, and the lower surface of the metal oxide semiconductor layer. The different positions include a plurality of positions on the curve with different curvature centers.

Taking the above-mentioned first contact region as an example, the second contact region is similar. In the above-mentioned different embodiments, the first contact region correspondingly determines the first angle, and the second contact region correspondingly determines the second angle. The repeated portions are omitted herein.

In the above-mentioned embodiment of the present application, the stacked structure at least includes the first semiconductor layer 105′ and the second semiconductor layer 106′, and the first semiconductor layer 105′ is closer to and in contact with the source electrode and the drain electrode.

The stacked structure including the first semiconductor layer 105′ and the second semiconductor layer 106′ can have the following various embodiments.

Illustratively, as illustrated by FIG. 1C, the stacked structure only includes a first semiconductor layer 105′ and a second semiconductor layer 106′, which are in direct contact, the first semiconductor layer 105′ is in contact with a gate insulating layer GI, and the second semiconductor layer 106′ is in contact with the source electrode and the drain electrode.

Illustratively, as illustrated by FIG. 1D, the stacked structure only includes a first semiconductor layer 105′, a second semiconductor layer 106′, and an obvious transition layer 800 formed by the contact between the first semiconductor layer 105′ and the second semiconductor layer 106′. The transition layer 800 is a metal oxide semiconductor layer, and the film quality of the transition layer 800 is different from that of the first semiconductor layer 105′ and the second semiconductor layer 106′. The transition layer 800 has a certain thickness, for example, an obvious layered structure can be seen under an electric microscope, and the thickness is about nanometer level.

Illustratively, as illustrated by FIG. 1E, the stacked structure includes a first semiconductor layer 105′ and a second semiconductor layer 106′, and further includes a third semiconductor layer 107′ located between the first semiconductor layer 105′ and the second semiconductor layer 106′. The carrier mobility of the third semiconductor layer 107′ is smaller than that of the first semiconductor layer 105′. The third semiconductor layer 107′ may have a film quality different from that of the first semiconductor layer 105′ and the second semiconductor layer 106′, or it may have an obvious layered structure as seen by an electric microscope. The third semiconductor layer can be a film layer formed by a different target material or the same target material and different process conductions from the first semiconductor layer 105′ and the second semiconductor layer 106′. One side of the third semiconductor layer 107′ is in contact with the first semiconductor layer 105′ and the other side of the third semiconductor layer 107′ is in contact with the second semiconductor layer 106′. Exemplary, the contact region of the third semiconductor layer 107′ with at least one of the first semiconductor layer 105′ and the second semiconductor layer 106′ bas no transition layer. Illustratively, the contact region of the third semiconductor layer with at least one of the first semiconductor layer 105′ and the second semiconductor layer 106′ has a transition layer with a certain thickness, for example, an obvious layered structure can be seen under an electric microscope, and the thickness is about nanometer level. The film quality of the transition layer is different from that of the first semiconductor layer 105′ and the second semiconductor layer 106′.

Illustratively, as illustrated by FIG. 1F, the stacked structure includes a first semiconductor layer 105′ and a second semiconductor layer 106′, which are in direct contact with each other, or include other semiconductor layers, but there is a fourth semiconductor layer 108′ below the first semiconductor layer 105′ and between the first semiconductor layer 105′ and the gate insulating layer. The carrier mobility of the fourth semiconductor layer 108′ is smaller than that of the first semiconductor layer.

FIGS. 1C to 1F just illustrate the stacked structure of the film layer, and do not illustrate the lateral shape of the film layer. In other words, the FIGS. 1C to 1F are only partial schematic diagrams of the semiconductor layer and do not include the lateral shape.

As illustrated by FIG. 1A, the first contact region 105 and the second contact region 106 on the oxide semiconductor layer have a shape provided as follows: the shape has a first angle α between the lower surface of the metal oxide semiconductor layer and the lateral surface of the first contact region, and a second angle β between the lower surface of the metal oxide semiconductor layer and the lateral surface of the second contact region; the first angle α is larger than the second angle β.

In the present embodiment, the carrier mobility of the first semiconductor layer is higher than that of the second semiconductor layer, and the fact that the first angle is larger than the second angle indicates that the area of the lateral surface of the first contact region decreases and the area of the lateral surface of the second contact region increases. Correspondingly, among the lateral regions, the area proportion of the lateral surface of the first semiconductor layer with higher carrier concentration decreases and the area proportion of the lateral surface of the second semiconductor layer with lower carrier concentration increases. The proportion of direct contact between the source electrode and the drain electrode and the first semiconductor layer with high carrier concentration can be reduced, and the characteristic defects of the semiconductor device when it is turned on can be reduced.

In the above-mentioned embodiment, the first semiconductor layer and the second semiconductor layer are semiconductor layers with different film qualities, such as film layers with different elemental compositions or film layers with different electrical or physical characteristics. For example, film layers with different oxygen contents, film layers with different metal element compositions (for example, different kinds of metal elements or different film layers), film layers with different molar ratios of metal elements, film layers with different band gaps, film layers with different hall mobility, film layers with different crystallinity, film layers with different densities, film layers with different etching rates, etc.

In the above-mentioned embodiment, upon the first angle α and the second angle β being determined, they may be included angles between the first contact region 105 and the second contact region 106 and the lower surface of the metal oxide semiconductor layer at the same position. For example, as illustrated by FIG. 1A, a certain cross section includes a first contact region 105 and a second contact region 106, and the included angles between the lateral surface of the first contact region and the lateral surface of the second contact region and a part of the lower surface of the metal oxide semiconductor layer close to the first contact region.

The angle between the two surfaces in the above-mentioned embodiment can be understood as that: the first angle is the first angle α between at least a part of the first contact region on the metal oxide semiconductor layer and a flat surface parallel to the lower surface of the metal oxide semiconductor layer and intersecting with the first contact region (this flat surface is a virtual flat surface), and the second angle is the second angle β between at least a part of the second contact region and a flat surface parallel to the lower surface of the metal oxide semiconductor layer and intersecting with the second contact region (this flat surface is a virtual flat surface).

In some embodiments, in the case where the first contact region and the second contact region are flat surfaces or similarly flat surfaces, the first angle is the included angle between the lateral surface and the lower surface of the oxide semiconductor layer.

In some embodiments, at least one of the first contact region and the second contact region is a convex surface or a concave surface, and the first angle α or the second angle β is the included angle between a tangent plane at a certain position of the convex surface or the concave surface and the lower surface of the oxide semiconductor layer, or the average value or minimum value of the included angles between the tangent planes at multiple positions and the lower surface of the oxide semiconductor layer.

For example, the first angle α and the second angle β can also be referred to as slope angles.

In some embodiments, the first contact region is all or a part of the region where the first semiconductor layer is in contact with the source electrode or the drain electrode. The second contact region is all or a part of the region where the second semiconductor layer is in contact with the source electrode or the drain electrode.

In one embodiment, the first contact region is all or a part of the region where the first semiconductor layer is in contact with the source electrode or the drain electrode: in the longitudinal section of some positions of the oxide semiconductor layer, the first contact region covers all lateral surface contours (corresponding to all regions in the contact regions) or a part of lateral surface contours (corresponding to a part of the regions in the contact regions) in the cross-sectional view of the first semiconductor layer.

The second contact region is all or a part of the region where the second semiconductor layer is in contact with the source electrode or the drain electrode: in the longitudinal section of some positions of the oxide semiconductor layer, the first contact region covers all lateral surface contours (corresponding to all regions in the contact region) or a part of lateral surface contours (corresponding to a part of the regions in the contact region) in the cross-sectional view of the first semiconductor layer.

In another example, the first contact region 105 may be the entire lateral surface of the source electrode or the drain electrode being in contact with the lower semiconductor layer, and the second contact region 106 may be the entire lateral surface of the source electrode or the drain electrode being in contact with the upper semiconductor layer. The first angle α is larger than the second angle β, which can increase the retraction degree of the upper semiconductor layer and decrease the size of the tail of the lower semiconductor layer and increase the slope angle of the lower semiconductor layer, so that the contact area of the source electrode or the drain electrode with the upper semiconductor layer can be increased and the contact area of the source electrode or the drain electrode with the lower semiconductor layer can be reduced.

Satisfying that the first angle α is larger than the second angle β in the above-mentioned embodiment the metal oxide semiconductor layer has the following different lateral shapes.

In one example, as illustrated by FIG. 1, in the longitudinal sectional contour of some positions of the oxide semiconductor layer, for at least part or all of the contour of the first contact region 105 or the second contact region 106, in the thickness direction of the metal oxide semiconductor layer 102, the longitudinal sectional contour of the lateral surface has a combination of one or at least two of the following different embodiments. The first contact region 105 is taken as an example to illustrate:

In one example, the first angle α is a constant value or a variable value close to constant value with a variation of no more than 3 degrees at different positions in the lateral longitudinal section, and its shape has no obvious concave or convex structure.

As illustrated by FIG. 1A, in another example, the first angle α varies greatly at different positions in the lateral longitudinal section, and the shape has obvious concave or convex structure. For example, the further the distance from the lower surface 102a is, the larger the first angle α is, and the lateral surface has a concave structure.

As illustrated by FIG. 1A, in another example, the further the distance from the lower surface 102a is, the first angle α first increases and then decreases, and the distance from the center position of the metal oxide semiconductor layer first increases and then decreases, and the lateral surface forms a concave and convex lateral surface.

In the left lateral surface in the figure, the lateral surface 102c includes a first contact region 105 and a second contact region 106. The further the distance between the first contact region 105 and the lower surface 102a is, the first angle α first increases and then decreases, and the distance between the first contact region 105 and the center position of the metal oxide semiconductor layer first decreases and then increases, and the lateral surface forms a concave surface. The second contact region 106 forms a continuous slope that retracts inward, and the slope surface is a plane rather than an obvious curved surface.

The center position may be the geometric center of the metal oxide semiconductor layer or the geometric center of the upper surface.

In another example, for example, as illustrated by FIG. 1A, the lateral surface 102c includes a first contact region 105 and a second contact region 106 in the longitudinal sectional view of the lateral surface on the right side of the figure. The further the distance between the first contact region 105 and the lower surface 102a is, the first angle α gradually increases. The first angle α ends at the position where the first angle α is the largest and enters the second contact region 106 at the position where the first angle α is the largest.

For example, as illustrated by FIG. 1, the first semiconductor layer is located between the second semiconductor layer and the base substrate, and the second semiconductor layer is located between the source-drain layer and the first semiconductor layer. For the bottom gate TFT, the first semiconductor layer can also be called as the lower semiconductor layer, and the second semiconductor layer can also be called as the upper semiconductor layer.

For example, in one example, as illustrated by FIGS. 1A, 1C to 1F, the crystallinity of the metal oxide of the first semiconductor layer 105′ is smaller than that of the metal oxide of the second semiconductor layer 106′. That is, the closer to the source electrode and the drain electrode, the greater the crystallinity of the whole of the metal oxide semiconductor layer, and the greater the crystallinity, the more favorable it is to reduce the risk of defects caused to the semiconductor layer when the source electrode and the drain electrode are etched.

For example, the stacked metal oxide semiconductor layer has a stacked structure shown in FIGS. 1C to 1F, and, in a direction perpendicular to the main surface of the base substrate 101, an extension distance d1 of the first contact region 105 from a position closest to the upper surface 102b to a position closest to the lower surface 102a is smaller than an extension distance d2 of the second contact region 106 from a position closest to the upper surface 102b to a position closest to the lower surface 102a. That is, the design makes that the size of the first contact region 105 in the direction perpendicular to the main surface of the base substrate 101 is smaller than that of the second contact region 106 in the direction perpendicular to the main surface of the base substrate 101.

Taking the stacked metal oxide semiconductor layer as illustrated by FIG. 1C as an example, and the stacked metal oxide semiconductor layer as illustrated by FIG. 2 as an example, and a width of an orthographic projection of the first contact region on the base substrate is L1; a width of an orthographic projection of the second contact region on the base substrate is L2; L1 is less than L2.

Taking the stacked metal oxide semiconductor layer as illustrated by FIG. 1C as an example, in some embodiments, the L2 is between 2 nm and 50 nm, and the L2 is 2 to 5 times that of L1. For example, L1 is 0.1 nm to 2 nm, and L2 is 2 nm to 10 nm.

Taking the stacked metal oxide semiconductor layer as illustrated by FIG. 1C as an example, in some embodiments, as illustrated by FIG. 2, the width L1 of the orthographic projection of the first contact region on the base substrate is smaller than the width L2 of the orthographic projection of the second contact region on the base substrate.

Taking the stacked metal oxide semiconductor layer as illustrated by FIG. 1C as an example, for example, it can be seen from FIGS. 1A and 2 that an orthographic projection of an lateral edge of the first contact region 105 adjacent to the lower surface 102a on the base substrate 101 is A, an orthographic projection of a lateral edge of the first contact region 105 adjacent to the second contact region 106 on the base substrate 101 is B, and an orthographic projection of a lateral edge of the second contact region 106 adjacent to the upper surface on the base substrate 101 is C.

Taking the stacked metal oxide semiconductor layer as illustrated by FIG. 1C as an example. For example, FIG. 2 is a schematic planar structure diagram of orthographic projections A-A′ and B-B′ of lateral edges of the first contact region respectively adjacent to the lower surface and the second contact region on the base substrate, and an orthographic projection C-C′ of a lateral edge of the second contact region adjacent to the upper surface on the base substrate provided by an embodiment of the present disclosure. As illustrated by FIG. 2, a distance between the orthographic projection A-A′ of the lateral edge of the first contact region 105 adjacent to the lower surface on the base substrate 101 and the orthographic projection B-B′ of the lateral edge of the first contact region 105 adjacent to the second contact region 106 on the base substrate 101 is L1, a distance between the orthographic projection B-B′ of the lateral edge of the first contact region 105 adjacent to the second contact region 106 on the base substrate 101 and the orthographic projection C-C′ of the lateral edge of the second contact region 106 adjacent to the upper surface 102b on the base substrate 101 is L2, and L1 is smaller than L2. That is, the distance L1 between the orthographic projections of the lateral edges of the first contact region 105 respectively adjacent to the lower surface 102a and the second contact region 106 on the base substrate 101 is smaller than the distance L2 between the orthographic projections of the lateral edges of the second contact region 106 respectively adjacent to the upper surface 102b and the first contact region 105 on the base substrate 101.

Although each of the above-mentioned embodiments takes the stacked metal oxide semiconductor layer as illustrated by FIG. 1C as an example, it is also applicable to other embodiments in FIGS. 1A to 1F.

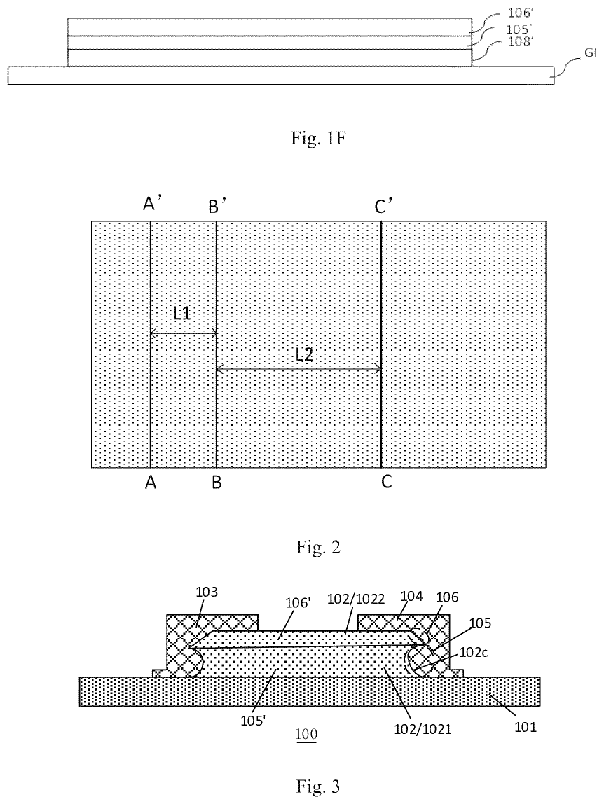

For example, FIG. 3 is a schematic diagram of a longitudinal section structure of another metal oxide thin film transistor provided in at least one embodiment of the present disclosure, which is applicable to the embodiments of FIGS. 1C to 1F. As illustrated by FIG. 3, taking the stacked structure of FIG. 1C as an example, the metal oxide semiconductor layer 102 includes a first semiconductor layer 1021 and a second semiconductor layer 1022 which are stacked; the source electrode 103 and the drain electrode 104 extend from the first semiconductor layer 1021 located on the lateral surface 102c to the second semiconductor layer located on the lateral surface 102c and the upper surface 102b, that is, the source electrode 103 and the drain electrode 104 both cover the upper surface of the second semiconductor layer, the lateral surface of the second semiconductor layer, and the lateral surface of the first semiconductor layer 1021.

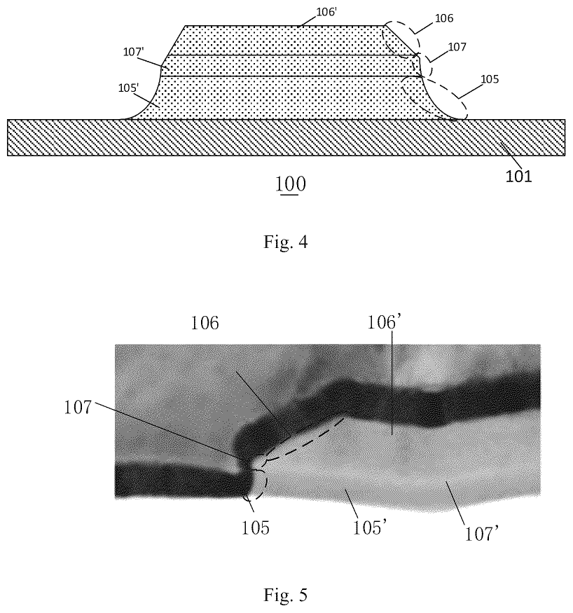

Taking the stacked metal oxide semiconductor layer shown in FIG. 1D as an example, and FIG. 4 is a cross-sectional view of a TFT semiconductor layer having a lateral shape. The metal oxide semiconductor layer further includes a transition layer, the transition layer is located between the first semiconductor layer and the second semiconductor layer and directly contacts with the first semiconductor layer and the second semiconductor layer.

In practical application, as illustrated by FIG. 1D, the transition layer 800 is a contact layer with a certain thickness formed after the first semiconductor layer and the second semiconductor layer are in contact, and the film quality of the transition layer 800 is different from that of the first semiconductor layer and the second semiconductor layer. For example, the crystallinity of the metal oxide of the transition layer 800 is larger than that of the metal oxide of the first semiconductor layer and smaller than that of the metal oxide of the second semiconductor layer. For example, the carrier concentration of the transition layer 800 is smaller than that of the first semiconductor layer.

The transition layer 800 may be a contact surface between the first semiconductor layer 105′ and the second semiconductor layer 106′ as illustrated by FIG. 3, the contact surface has a small thickness, and there is no obvious measurable or observable semiconductor layer with a certain thickness. The transition layer may also be a third semiconductor layer 107′ with a certain thickness as illustrated by FIG. 4.

As illustrated by FIG. 4, there is a corner region 107 between the first contact region 105 and the second contact region 106. An edge of the first contact region 105 adjacent to the second contact region 106 is located in the corner region 107, and the third semiconductor region 107′ includes a corner region 107, which is a transition region of electrical or physical characteristics such as lattice or carrier concentration between the first semiconductor layer 105′ and the second semiconductor layer 106′.

The shape of the stacked metal oxide semiconductor will be described below by taking the case where there is an obvious transition region (third semiconductor region 107′) between the first semiconductor layer 105′ and the second semiconductor layer 106′ as an example. Of course, the shape of the stacked metal oxide semiconductor described in the following is also applicable to the lateral shape of each stacked structure shown in FIGS. 1A to 1F.

In some embodiments, the first contact region is a first flat surface or a first concave surface, and the second contact region is a second flat surface or a second concave surface. In some embodiments, the first contact region is the first concave surface, and at least a part of the first concave surface is located in the first semiconductor layer.

In some embodiments, in a direction away from the lower surface of the first concave surface, the first angle increases first and then decreases, and the distance from the center position of the metal oxide semiconductor layer decreases first and then increases.

In some embodiments, the difference of the first angles of different positions in the direction away from the lower surface in the first concave surface does not exceed 3 degrees. Or, in the direction away from the lower surface in the first concave surface, the first angle gradually increases, and the position with the largest first angle is adjacent to the second contact region.

In some embodiments, the first contact region is the first concave surface, and the values of the first angles α between different positions of the first contact region and the lower surface are the same value or a plurality of different values; the second contact region is a smooth second flat surface, and the second angles β between different positions of the second contact region and a flat surface parallel to at least a part of the lower surface and intersecting with the second contact region have the same value or a plurality of different values.

For example, the first contact region 105 is a first flat surface or a first concave surface, and the second contact region 106 is a second flat surface or a second concave surface. As illustrated by FIG. 4, the first contact region 105 is the first concave surface and the second contact region 106 is the second flat surface. The first concave surface is only distributed in the first semiconductor layer 105′, and the second flat surface is only distributed in the second semiconductor layer 106′. In other examples, the first contact region 105 may be a first flat surface, and the second contact region 106 may be a second concave surface. Alternatively, the first contact region 105 may be the first concave surface, and the second contact region 106 may be the second concave surface. Alternatively, the first contact region 105 may be the first flat surface, and the second contact region 106 may be the second flat surface, which are not limited by the embodiments of the present disclosure.

For example, FIG. 5 is a transmission electron microscope scanning schematic diagram of a cross-sectional structure of a metal oxide thin film transistor provided by at least one embodiment of the present disclosure, which corresponds to the schematic diagram shown in FIG. 4. FIG. 4 shows the transition region more clearly, the thickness of the transition region accounts for a large proportion, but in practical application, some embodiments are similar to those shown in FIG. 5, and the thickness of the transition region is relatively small.

In some embodiments, the metal oxide semiconductor layer 102 included in the metal oxide thin film transistor 100 includes three regions, including the first semiconductor layer 105′, the second semiconductor layer 106′ and the third semiconductor region 107′ as illustrated by FIG. 4. For example, referring to FIGS. 4 and 5, the metal oxide semiconductor layer 102 includes the first semiconductor layer 105′ with a detectable amorphous structure or nano-crystalline structure which is close to the base substrate 101 or an insulating layer, a second semiconductor layer 106′ with a detectable crystalline structure away from the base substrate 101, and a third semiconductor region 107′ between the first semiconductor layer 105′ and the second semiconductor layer 106′. In the metal oxide semiconductor layer 102, the crystallinity of the first semiconductor layer 105′ is the smallest, the crystallinity of the second semiconductor layer 106′ is the largest, and the crystallinity of the third semiconductor region 107′ is between that of the first semiconductor layer 105′ and that of the second semiconductor layer 106′. That is, in the direction from the upper surface 102b to the lower surface 102a, the crystallinity of the metal oxide semiconductor layer 102 gradually decreases, and the lateral surface 102c includes a concave surface that is depressed toward the geometric center of the stereoscopic structure of the metal oxide semiconductor layer 102.

For example, in one embodiment, crystals or a large number of amorphous structures cannot be detected in a part of all of the first semiconductor layer 105′ which is close to the base substrate 101 at a plurality of test points. A large number of single crystals or poly crystals can be detected in a part of all of the second semiconductor layer 106′ away from the base substrate 101 at a plurality of test points. A mixed crystalline state can be detected in the third semiconductor region 107′ between a position close to the base substrate 101 and a position away from the base substrate 101, and the crystallinity of the mixed crystalline state is located between the first semiconductor layer 105′ and the second semiconductor layer 106′. The third semiconductor region 107′ may be very thin and distributed between the first semiconductor layer 105′ and the second semiconductor layer 106′.

For example, in one embodiment, the change from the amorphous state to the crystalline state can be two obviously different degrees of crystallinity that can be detected in the metal oxide semiconductor layer 102, for example, the obvious change from the first crystallinity to the second crystallinity.

For example, in one example, the metal oxide semiconductor layer with the first crystallinity is a film layer close to the base substrate, and its crystallinity is completely amorphous or crystalline. This completely amorphous property is that crystals cannot be observed under the test equipment. The crystalline property is between completely amorphous and single crystal or poly crystal, which is a transition state between completely amorphous and crystalline, and can be at least a combination of one or more of the following.

(1) There are nano crystals in the complete amorphous state with low crystallinity (also called CAC-cloud-aligned composite).

(2) It includes relatively large amount of nanograins (also called nc-OS). The size of nanograins is about 1 nm to 10 nm, such as 1 nm to 3 nm. This kind of film layer has high conductivity and relatively few impurities.

The above-mentioned metal oxide semiconductor layer with the second crystallinity, for example, the crystallinity of the region away from the base substrate 101 is crystal, for example, poly crystalline or single crystal, or the crystallinity is crystal (CAAC) with C-axis orientation (i.e., the direction perpendicular to the base substrate), i.e., crystal with multi-layered distribution in the C-axis direction. It has the characteristics of difficult film etching, favorable back channel etching structure, low impurity and low leakage current of thin film transistor. The crystallinity of crystal with multi-layered distribution in the C-axis direction is larger than that of nano crystals with small crystallinity, and smaller than that of single crystal or poly crystal.

For example, as illustrated by FIG. 5, the first concave surface is a curved surface. and the contour of the longitudinal section of the curved surface from the lower surface 102a to the upper surface 102b of the metal oxide semiconductor layer 102 includes an arc or an elliptical arc. For example, in FIG. 5, the case where the longitudinal section of the outer contour of the first concave surface is ½ elliptical arc is taken as an example. Of course, in other embodiments, the longitudinal section of the outer contour of the first concave surface may also be ¼ elliptical arc, ⅓ elliptical are, etc.

For example, as illustrated by FIG. 5, the lower surface 102a and the upper surface 102b of the metal oxide semiconductor layer 102 are parallel to the surface of the base substrate 101 on which the metal oxide semiconductor layer 102 is provided, and the direction from the lower surface 102a to the upper surface 102b or from the upper surface 102b to the lower surface 102a is the thickness direction of the metal oxide semiconductor layer 102.

For example, in one embodiment, a region of the lateral surface 102ccorresponding to a middle region of the metal oxide semiconductor layer 102 along the thickness direction is the third semiconductor region 107′, which is a transition layer region between the first semiconductor layer 105′ and the second semiconductor layer 106′. The film quality of the transition layer region is different from that of the first semiconductor layer and the second semiconductor layer, and the difference can be the difference of electrical characteristics or physical characteristics. For example, the crystallinity of the metal oxide of the third semiconductor layer is larger than the crystallinity of the metal oxide of the first semiconductor layer and smaller than the crystallinity of the metal oxide of the second semiconductor layer. For example, the carrier concentration of the third semiconductor layer is smaller than that of the first semiconductor layer.

For example, in the manufacturing process of the product, the first semiconductor layer 105′ and the second semiconductor layer 106′ can be formed by two kinds of metal oxide target materials or two process parameters of one target material. After the formation, due to the different materials or crystallinity of the two film layers, an interface layer will be formed between the two film layers formed by the two process parameters of the two target materials or one target materials. The crystal state of the interface layer is mixed with the crystal state of the first semiconductor layer 105′ and the second semiconductor layer 106′ at the same time, or does not have the crystal state of the first semiconductor layer 105′ and the second semiconductor layer 106′ but a new mixed state is generated, which is different from the crystal state of the first semiconductor layer 105′ and the second semiconductor layer 106′, but the crystallinity is between the first semiconductor layer 105′ and the second semiconductor layer 106′.

For example, as illustrated by FIG. 5, the lateral surface of the second contact region 106 close to the upper surface 102b is inclined.

With respect to the slope of the second contact region 106 close to the upper surface 102b, in other words, the lateral surface 102c includes a slope with a slope angle that is concave toward the geometric center of the stereoscopic structure of the metal oxide semiconductor layer 102. All or a part of the inclined surface is located in the second semiconductor layer 106′.

It should be noted that the etching solution used in the embodiment of the present disclosure includes more than 60% moisture, and its etching rate to a part close to the lower surface 102a is very low, so that it does not have too big undercut phenomenon, and the source electrode or the drain electrode formed on the outside has a good shape and is not easy to break.

For example, in some embodiments, the circular arc or the elliptical arc of the longitudinal section from the upper surface 102b to the lower surface 102a of the metal oxide semiconductor layer 102 does not exceed a semi-circular arc or a semi-elliptical arc, and the maximum depth of the curved surface does not exceed 50 nm and is not less than 1 nm. For example, in some embodiments, the maximum depth of the curved surface is no more than 10 nm and no less than 2 nm.

For example, if the thickness of the whole metal oxide semiconductor layer 102 is not more than 100 nm, and the thickness of the first semiconductor layer 105′ is in the range of 5 nm to 20 nm, the depth is not more than half of the circular arc, that is, 10 nm.

For example, in some embodiments, the lateral surfaces of the third semiconductor region 107′ and the first semiconductor layer 105′ include curved surfaces with circular arc or elliptical arc. That is, the circular arc or the elliptical arc is located in the first semiconductor layer 105′ or the third semiconductor region 107′. Because the etching solution etches the metal oxide of the first semiconductor layer 105′ and the third semiconductor region 107′ at a slower rate or has a smaller contact region with the etching solution, the etching rate for the metal oxide of the second semiconductor layer 106′ is faster or the contact area with the etching solution is larger, so that the lateral surface of the second semiconductor layer 106′ is etched more to form a slope.

For example, in some embodiments, the lateral surface 102c includes an inclined surface with a slope angle that is concave toward the geometric center of the stereoscopic structure of the metal oxide semiconductor layer 102, and all or a part of the inclined surface is located in the second semiconductor layer 106′.

For example, because the metal oxide semiconductor layer 102 is etched in a moving state, the etching solution spraying equipment is arranged at a fixed position, and the metal oxide semiconductor layer 102 on the lower moving substrate is sprayed from top to bottom, so that the surface first contacting the etching solution is the upper surface (the second main surface) and the surface later contacting the etching solution is the lateral surface along the thickness direction of the metal oxide semiconductor layer 102. FIG. 5 shows a transmission electron microscope scanning schematic diagram including a metal oxide semiconductor layer 102, including a source electrode 103 above the metal oxide semiconductor layer 102, and a longitudinal cross-sectional structure of the left lateral surface of the overall structure.

It should be noted that FIG. 5 only shows a part of the scanning schematic diagram of transmission electron microscope, omitting the insulating layers and the base substrate below the metal oxide semiconductor layer 102 and other film layers above the source electrode 103.

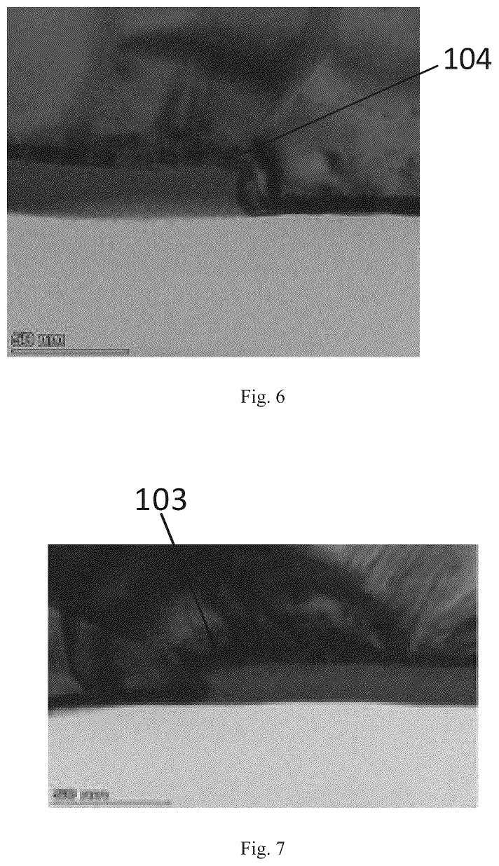

For example, FIG. 6 shows a cross-sectional structure of an upper surface of a metal oxide semiconductor layer, and FIG. 7 shows a cross-sectional structure of a lower surface of a metal oxide semiconductor layer. The drain electrode 104 is clearly shown in FIG. 6, and the source electrode 103 is clearly shown in FIG. 7.

For example, as illustrated by FIG. 6, the lateral surface 102c includes a concave surface that is concave toward the geometric center of the stereoscopic structure of the metal oxide semiconductor layer 102, and the concave surface is ½ elliptical arc.

For example, as illustrated by FIG. 7, the lateral surface 102c includes a concave surface which is concave toward the geometric center of the stereoscopic structure of the metal oxide semiconductor layer 102, and the concave surface is ½ elliptical arc, and the concave degree of the elliptical arc shown in FIG. 7 is larger than that of the elliptical arc shown in FIG. 6, that is, the curvature of the elliptical arc shown in FIG. 7 is larger than that of the elliptical are shown in FIG. 6.

For example, in the structures shown in FIGS. 1A to 1F, and in the lateral contour structure shown in FIG. 5, the metal oxide semiconductor layer includes an overlapping region that at least partially overlaps with an orthographic projection of the source electrode or the drain electrode on the base substrate, and a non-overlapping region that does not overlap with the orthographic projection of the source electrode or the drain electrode on the base substrate.

In some embodiments, the content percentage of oxygen element of the overlapping region is smaller than that in the non-overlapping region, and the oxygen element of the overlapping region is relatively small, which is beneficial to improving the conductivity of the semiconductor in the source-drain contact region and reducing the contact resistance.

In some embodiments, the percentage difference of oxygen content between the non-overlapping region and the overlapping region is not less than 10%.

In some embodiments, the percentage difference of oxygen content between the non-overlapping region and the overlapping region ranges from 10% to 30%.

In some embodiments, the content percentage of oxygen element of the non-overlapping region is greater than 40%, and the content percentage of oxygen element of the overlapping region is less than 30%.

In some embodiments, the content percentage of oxygen element of the non-overlapping region is in the range of 38% to 58%; the content percentage of oxygen element of the overlapping region is in the range of 20% to 40%.

In some embodiments, at least a part of the non-overlapping region and the overlapping region include nitrogen element, and the content percentage of nitrogen element of the overlapping regions is smaller than that in the non-overlapping region.

In some embodiments, the content percentage of nitrogen element of the overlapping region is between 3% and 10%, and the content percentage of nitrogen element of the non-overlapping region is between 5% and 15%.

In some embodiments, both the non-overlapping region and the overlapping region include metal elements In (Indium) and Zn (Zinc), the difference between the content percentage of In and the content percentage of Zn in the overlapping region is smaller than that in the non-overlapping region, and in the non-overlapping region, the content percentage of In i is larger than the content percentage of Zn.

In some embodiments, both the non-overlapping region and the overlapping region include metal element In, and the content percentage of In in the overlapping region is greater than the content percentage of In in the non-overlapping region.

In some embodiments, the content percentage of In in the overlapping region is between 15% and 20%; the content percentage of In in the non-overlapping region is between 8% and 15%.

The material of the metal oxide semiconductor layer 102 includes at least two selected from the group consisting of In, Zn, Sn (Stannum), Ga (Gallium), etc., and may further include materials such as rare earth metals or Sn metal to improve the characteristics and mobility of the TFT. For example, the metal oxide semiconductor layer 102 is at least one of n-type semiconductor materials such as zinc oxide (ZnO), indium oxide (In₂O₃), indium zinc oxide (IZO), aluminum-doped zinc oxide (AZO), boron-doped zinc oxide (BZO), magnesium-doped zinc oxide (MZO), zinc tin oxide (ZTO), indium gallium zinc oxide (IGZO), indium tin zinc oxide (ITZO), gallium zinc oxide (GZO), indium tin oxide (ITO), hafnium indium zinc oxide (HIZO), and stannic oxide (SnO₂), or at least one of p-type semiconductor materials such as stannous oxide (SnO) and cuprous oxide (Cu₂O).

For example, the metal oxide semiconductor layer 102 can be formed by magnetron sputtering, reactive sputtering, anodizing or spin coating.

For example, the metal oxide semiconductor layer 102 is formed on an insulating layer; for example, in a top gate structure, the metal oxide semiconductor layer 102 is formed on a buffer layer, which is generally an oxide containing silicon element, a nitride element, or an oxynitride; in a bottom gate structure, the metal oxide semiconductor layer 102 is formed on the gate insulating layer.

For example, the base substrate 101 is formed of a rigid material or a flexible material. For example, the rigid material includes one of rigid glass and silicon wafer. The flexible material includes one of polyethylene naphthalate, polyethylene terephthalate, polyimide and flexible glass.

For example, in one example, the first contact region 105 is a first concave surface, and the value of the first angles α between different positions of the first contact region 105 and the lower surface 102a are the same value or a plurality of different values.

The second contact region 106 is a smooth second concave surface, and the second angles β between different positions of the second contact region 106 and the flat surface parallel to at least a part of the lower surface 102a and intersecting with the second contact region 106 have a series of continuously changing values, that is, the second angles β between different positions of the second contact region 106 and the flat surface parallel to at least a part of the lower surface 102a and intersecting with the second contact region 106 can take uninterrupted values within a certain range.

For example, in one example, a corner is formed between the first contact region 105 and the second contact region 106. The corner is an included angle between two surfaces that form an angle, and the corner is an obtuse angle.

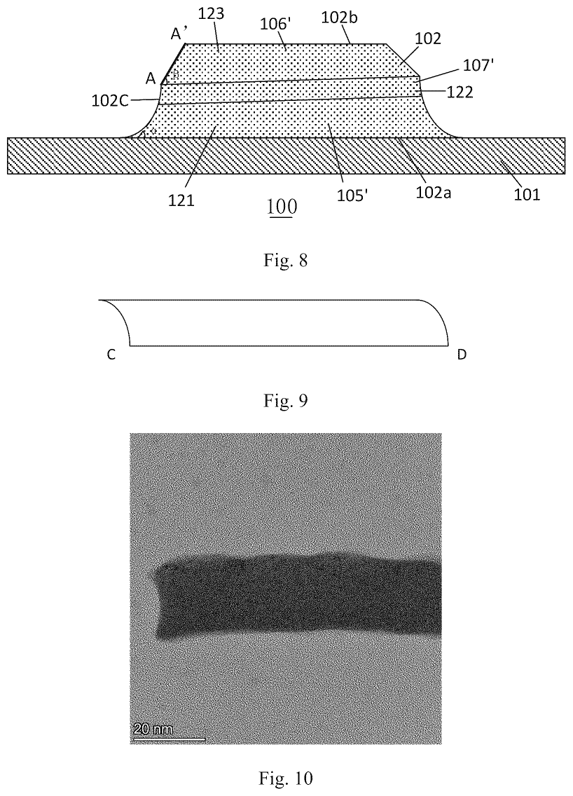

For example, FIG. 8 is a schematic cross-sectional structure diagram of another metal oxide thin film transistor provided by at least one embodiment of the present disclosure. As illustrated by FIG. 8, the first semiconductor layer 105′ includes amorphous or nano-crystalline IGZO; the second semiconductor layer 106′ includes C-axis aligned crystalline (CAAC) IGZO.

For example, the thickness of the first semiconductor layer 105′ is 5 nm to 20 nm. For example, 5 nm to 10 nm, 10 nm to 15 nm, or 15 nm to 20 nm.

For example, the thickness of the second semiconductor layer 106′ is 20 nm to 60 nm, or 60 nm to 100 nm. For example, 20 nm to 25 nm, 25 nm to 30 nm, 35 nm to 45 nm, and 50 nm to 60 nm.

For example, a ratio of the thickness of the second semiconductor layer 106′ to the thickness of the first semiconductor layer 105′ ranges from 0.2 to 5. For example, the ratio of the thickness of the second semiconductor layer 106′ to the thickness of the first semiconductor layer 105′ is 0.2 to 1, 1.2 to 2, and 2 to 5.

For example, in one example, the thickness of the second semiconductor layer 106′ is greater than that of the first semiconductor layer 105′, for example, the thickness of the first semiconductor is 5 nm to 20 nm, and the thickness of the second semiconductor is 20 nm to 100 nm. One embodiment is that the thickness of the first semiconductor is 5 nm to 15 nm, and the thickness of the second semiconductor is 20 nm to 35 nm.

For example, in one example, the metal oxide semiconductor layer 102 includes indium element, gallium element and zinc element. In the metal oxide semiconductor layer 102, the element distribution in at least some regions satisfies the following requirements: a molar ratio of zinc element to indium element is (2 to 4):(3 to 5), and the molar ratio of zinc element to gallium element is (2 to 4):(1 to 2).

For example, the material of the metal oxide semiconductor layer 102 includes indium element, gallium element, and zinc element. For example, a film layer formed by indium gallium zinc oxide or indium gallium zinc oxide doped (IGZO-B) target material, for example, after depositing an indium gallium zinc oxide film (IGZO-B) in a low-oxygen environment of a chamber, the equipment has a pressure-stabilizing time of 20 s with a changing atmosphere, and the pressure-stabilizing atmosphere is 100% oxygen. The surface of the target material and the glass surface can absorb more oxygen in an oxygen enriched state, and it is easier for the zinc element to be combined with oxygen element. As a result, the interface layer is rich in zinc, while the content of indium in the interface layer is relatively low. In the metal oxide semiconductor layer formed by IGZO, indium is responsible for providing carrier channel, gallium has high ionization energy to inhibit electron mobility, and zinc can combine with strong chemical bonds of oxygen ions to form a stable tetrahedral structure. And B in the IGZO-B is a certain type of doping element. The IGZO mentioned in this paragraph is only used to explain the elemental composition of the film, but not to limit its molar ratio.

The metal oxide semiconductor layer comprises a channel region and a channel protection region which are stacked; the first semiconductor layer corresponds to the channel region, the second semiconductor layer corresponds to the channel protection region, and the source electrode or the drain electrode extends from the channel region of the lateral surface to the channel protection regions of the lateral surface and the upper surface.

A transition region is formed between the channel region and the channel protection region, and the crystallinity of the film layer in the transition region is smaller than that of the channel protection region but larger than that of the channel region, and the film layer is a metal oxide semiconductor layer.

For example, in one example, the metal oxide semiconductor layer 102 includes an amorphous layer or a nano-crystalline layer 121, a crystalline layer 123, and a transition layer 122 with a crystalline state between the amorphous layer or nano-crystalline layer and the crystalline layer, which is located between the amorphous layer or nano-crystalline layer 121 and the crystalline layer 123 in the thickness direction of the metal oxide semiconductor layer 102. In the thickness direction of the metal oxide semiconductor layer 102, the crystallinity of the metal oxide semiconductor layer 102 varies from the lower surface 102a to the upper surface 102b, and amorphous or nano-crystalline metal oxide semiconductors are distributed in the region close to the lower surface 102a, while crystalline metal oxide semiconductors are distributed in the region close to the upper surface 102b, that is, the crystallinity of the metal oxide semiconductor in the region close to the lower surface 102a is smaller than that close to the upper surface 102b.

It should be noted that although the metal oxide semiconductor layer 102 described in the embodiment of the present disclosure includes an amorphous layer or nano-crystalline layer 121, a transition layer 122 and a crystalline layer 123, there is no obvious boundary in the metal oxide semiconductor layer 102, and the corresponding metal oxides of the amorphous layer or nano-crystalline layer 121 are not all composed of amorphous metal oxides, but may also include partial crystalline metal oxides. The metal oxides corresponding to the crystalline layer 123 are not all composed of crystalline metal oxides, but may also include some amorphous metal oxides. The crystalline state of the transition layer 122 is not completely between amorphous state and the crystalline state, and may also include partially crystalline metal oxide and/or partially amorphous metal oxide, which is not limited by the embodiments of the present disclosure.

For example, although the boundary between the amorphous layer or nano-crystalline layer 121 and the transition layer, the boundary between the transition layer 122 and the crystalline layer 123 are shown by straight lines in FIG. 8, which do not refer to that the strict boundary between the amorphous layer or the nano-crystalline layer 121 and the transition layer 122, the boundary between the transition layer 122 and the crystalline layer 123, and the boundary between the amorphous layer or the nano-crystalline layer 121 and the transition layer, the boundary between the transition layer 122 and the crystalline layer 123 may be a curved line or a broken line, and embodiments of the present disclosure are not limited herein.

For example, in one example, in the metal oxide semiconductor layer 102, the thickness of the crystalline layer 123 is larger than the thickness of the amorphous layer or the nano-crystalline layer 121, and the thickness of the amorphous layer or the nano-crystalline layer 121 is larger than that of the transition layer 121. For example, the amorphous layer or the nano-crystalline layer 121 is mainly used as a carrier channel, and the transition layer 122 and the crystalline layer 123 are mainly used to protect the amorphous layer or the nano-crystalline layer 121 from being reduced.

For example, in one example, the molar ratio of indium element in the amorphous layer or the nano-crystalline layer 121 to indium element in the crystalline layer 123 is 0.97 to 1.38, and the molar ratio of indium element in the amorphous layer or the nano-crystalline layer 121 to indium element in the transition layer 122 is 1.36 to 1.64; the molar ratio of gallium element in the amorphous layer or the nano-crystalline layer 121 to gallium element in the crystalline layer 123 is 0.57 to 0.92, and the molar ratio of gallium element in the amorphous layer or nano-crystalline layer 121 to gallium element in the transition layer 122 is 0.5 to 1.1. The molar ratio of zine element in amorphous layer or nano-crystalline layer 121 to zinc element in crystalline layer 123 is 0.8 to 0.96, and the molar ratio of zinc element in amorphous layer or nano-crystalline layer 121 to zinc element in transition layer 122 is 0.74 to 0.83.

For example, in one example, the molar ratio of indium element in the amorphous layer or nano-crystalline layer 121 to indium element in the crystalline layer is 0.97 to 1.38, such as 1, 1.05, 1.12, 1.24, 1.31 or 1.38; and the molar ratio of the indium element in the amorphous layer or nano-crystalline layer 121 to the indium element in the transition layer 122 is 1.36 to 1.64, such as 1.38, 1.42, 1.53, 1.58 or 1.64.

For example, in one example, the molar ratio of gallium element in the amorphous layer or the nano-crystalline layer 121 to gallium element in the crystalline layer 123 is 0.57 to 0.92, such as 0.59, 0.62, 0.68. 0.74, 0.82 or 0.88; and the molar ratio of gallium element in the amorphous layer or the nano-crystalline layer 121 to gallium element in the transition layer 122 is 0.5 to 1.1, such as 0.55, 0.62, 0.68, 0.74, 0.82, 0.88, 0.94, 0.98 or 1.1.

For example, in one example, the molar ratio of zinc element in the amorphous layer or the nano-crystalline layer 121 to zinc element in the crystalline layer 123 is 0.8 to 0.96, such as 0.82, 0.86, 0.92, 0.94 or 0.96; and the molar ratio of zinc element in the amorphous layer or nano-crystalline layer 121 to zinc element in the transition layer 122 is 0.74 to 0.83, such as 0.75. 0.77, 0.79, 0.81 or 0.83.

For example, in one example, in the metal oxide semiconductor layer 102, the thickness of the amorphous layer or the nano-crystalline layer 121 is 50 angstroms to 200 angstroms, such as 50 angstroms, 80 angstroms, 100 angstroms, 120 angstroms, 140 angstroms, 160 angstroms, 180 angstroms or 200 angstroms. The thickness of the crystalline layer 223 is 80 angstroms to 400 angstroms, such as 100 angstroms, 120 angstroms, 180 angstroms, 220 angstroms, 260 angstroms, 300 angstroms, 360 angstroms or 400 angstroms. The thickness ratio of the crystalline layer 123 to the amorphous layer or the nano-crystalline layer 121 is 0.2 to 2, for example, 0.4, 0.6, 0.9, 1.2, 1.6, 1.8 or 2.

For example, as illustrated by FIG. 8, the transition layer 122 is retracted to the central region of the metal oxide semiconductor layer 102 relative to the crystalline layer 123, that is, each lateral surface of the transition layer 122 is retracted to the central area of the metal oxide semiconductor layer 102 relative to the crystalline layer 123, and the outermost edge of the transition layer 122 and the outermost edge of the crystalline layer 123 are not aligned on each lateral surface, so that the length of the transition layer 122 is shorter than that of the crystalline layer 123.

It should be noted that, in some embodiments, the transition layer 122 is an interface contact layer between the amorphous layer or the nano-crystalline layer 121 and the crystalline layer 123 formed after the amorphous layer or the nano-crystalline layer 121 and the crystalline layer 123 are respectively manufactured by a process. The thickness of the transition layer 122 is very thin, and it may be difficult to accurately observe the film layer, but it can be tested by testing the crystallinity that its crystallinity lies between the amorphous layer or the nano-crystalline layer 121 and the crystalline layer 123.

For example, as illustrated by FIG. 8, in the thickness direction of the metal oxide semiconductor layer 102, from the main surface of the base substrate 101 to the side away from the base substrate 101, the further the distance from the lower surface 102a is, the larger the first angle α between the first contact region 105 and the lower surface 102a is, and the closer the first contact region 105 is to the center position of the metal oxide semiconductor layer 102.

For example, as illustrated by FIG. 8, the cross-sectional shape of the first contact region 105 is a curved surface, which is a part of an elliptical cylinder. The slope angle of the curved surface first increases and then decreases along the direction from the lower surface 102a to the upper surface 102b, and in the thickness direction of the metal oxide semiconductor layer 102, that is, along the direction from the lower surface 102a to the upper surface 102b, the curved surface first extends towards the center of the metal oxide semiconductor layer 102 and then goes away from the center of the metal oxide semiconductor layer 102. For example, a part of the first contact region 105 close to the lower surface 102a has a gentle slope, so that the risk of the passivation layer and the traces on the passivation layer being broken can be reduced when the passivation layer and traces are formed later.

For example, as illustrated by FIG. 8, the outer contour of the first concave surface is 1/n circular arc, which may not be a strict 1/n circular arc, but may be any similar shape with a curved approximate shape of 1/n circular arc.

For example, in some embodiments, the outer contour of the lateral surface 12ccorresponding to an edge of the transition layer 122 and the amorphous layer or nano-crystalline layer 121 is a combination of a 1/n arc and an inclined surface.

Actually, upon the shape of the lateral surface of the metal oxide semiconductor layer 102 being observed microscopically, some inclined surfaces are very flat, similar to an arc tangent A-A′, and some inclined surfaces are not necessarily flat, but the whole looks like an inclined surface with a certain slope angle, which is not curved enough to define it as an obvious curved surface.

It should be noted that the arc of the outer contour of the curved surface does not exceed ½ of the entire circumference, and may be 1/32, 1/16, ⅛, ¼, ½ of the entire circumference, or wavy. The embodiment of the present disclosure is not limited thereto.

It should also be noted that in the above-mentioned first semiconductor layer 105′, second semiconductor layer 106′ and third semiconductor region 107′, it may not be easy to visually distinguish each film layer after TEM test. For example, although the metal oxide semiconductor layer 102 described in the embodiment of the present disclosure includes an amorphous layer or nano-crystalline layer 121, a transition layer 122 and a crystalline layer 123, the visual boundary of the metal oxide semiconductor layer 102 is not obvious enough during device inspection or lens test.

Although the boundary between the amorphous layer or the nano-crystalline layer 121 and the transition layer 122, the boundary between the transition layer 122 and the crystalline layer 123 are shown by oblique lines in FIG. 8, they do not refer to the strict boundaries between the amorphous layer or the nano-crystalline layer 121, the transition layer 122 and the crystalline layer 123, the boundary between the amorphous layer or the nano-crystalline layer 121 and the transition layer 122, the interface shape between the transition layer 122 and the crystalline layer 123 and the shape of the amorphous layer are similar to flat surfaces, unless the amorphous layer is formed on a surface of an uneven insulating layer.

In the above example, the metal oxide semiconductor corresponding to the crystalline layer 123 may be single crystal or poly crystalline or C-axis aligned crystal (CAAC). The crystalline state of the transition layer 122 includes tiny crystals, such as nano crystals, or a unique transition structure whose crystalline phase is difficult to determine, but it can be distinguished from the upper crystalline layer and the lower amorphous or nano-crystalline.

For example, except for a region where the crystal layer 123 is formed with a slope, the transition layer 122 is retracted to the central region of the metal oxide semiconductor layer 102 with respect to the crystal layer 123 (for example, the surface close to the base substrate 101), that is, each lateral surface of the transition layer 122 is retracted to the central region of the metal oxide semiconductor layer 102 with respect to the crystal layer 123, and the outermost edge of the transition layer 122 and the outermost edge of the crystal layer 123 are not aligned, so that the length of the transition layer 122 is shorter than that of the crystalline layer 123.

For example, as illustrated by FIG. 8, the outer contour of the edge of the lateral surface 102c corresponding to the region of the crystalline layer 123 is an inclined straight line, so that there is a first slope angle between the crystalline layer 123 and the horizontal flat surface. From the upper surface 102b to the lower surface 102a of the metal oxide semiconductor layer 102, the inclined straight line gradually extends away from the center of the crystalline layer 123 and is on each lateral surface 102c of the metal oxide semiconductor layer 102. The inclined straight line gradually extends away from the center of the crystalline layer 123. Upon the crystalline layer 123 being etched, the etching speed is keptuniform.

For example, as illustrated by FIG. 8, there is a convex corner between the inclined surface and the curved surface of the lateral surface 102c, and the edge of the lateral surface 102c corresponding to the region where the crystalline layer 123 and the transition layer 122 are adjacent has a convex corner protruding away from the center of the transition layer 122

For example, as illustrated by FIG. 8, a region of the lateral surface 102c corresponding to the crystalline layer 123 has a second angle β, which is an average value. A region of the lateral surface 102c corresponding to the amorphous layer or the nano-crystalline layer 121 and the transition layer 122 has a first angle α. In the first angle α formed along the tangent of the outer edge of the concave surface, the first angle α first increases and then decreases along the direction from the first main surface 102a to the second main surface 102b.

For example, as illustrated by FIG. 8, the curved surface of the lateral surface 102c is distributed on at least one lateral surface 102c of the metal oxide semiconductor layer 102 in multiple directions, and the generatrix forming the curved surface is parallel to the lower surface 102a of the metal oxide semiconductor layer 102, so that the curved surface extends from the first position of the lateral surface 102c to the direction close to the base substrate 101 with the generatrix as the axis.

For example. FIG. 9 is a schematic diagram of a cross-sectional structure of the curved surface in FIG. 8 from the outside to the inside perpendicular to the paper surface. As illustrated by FIG. 9, a straight line CD is used as a generatrix, and it is rotated along the generatrix CD to form a part of a cylindrical or elliptical column to form the concave shape of the cross section in FIG. 8. Combined with FIG. 8 and FIG. 9, the generatrix CD of the curved surface is parallel to the lower surface 102a of the metal oxide semiconductor layer 102. For example, the surface is a continuous surface.

For example, as illustrated by FIG. 8, the lateral surface 102c further includes a second contact region 106 extending from the first contact region 105 to the upper surface 102b. The second contact region 106 is an inclined surface. In the thickness direction of the metal oxide semiconductor layer 102, from the main surface of the base substrate 101 to the side away from the base substrate 101, the further away from the lower surface 102a, the closer the second contact region 106 is to the center of the metal oxide semiconductor layer 102, the distance between the lateral surface 102c formed by the first contact region 105 and the second contact region 106 and the center of the metal oxide semiconductor layer 102 decreases first, then increases and then decreases along the direction from the lower surface 102a to the upper surface 102b.

For example, FIG. 10 is a transmission electron microscope scanning schematic diagram of the cross-sectional structure of another metal oxide thin film transistor provided by at least one embodiment of the present disclosure. As illustrated by FIG. 10, the cross-sectional shape of the first contact region 105 has a first concave surface, and the cross-sectional shape of the second contact region 106 is inclined.

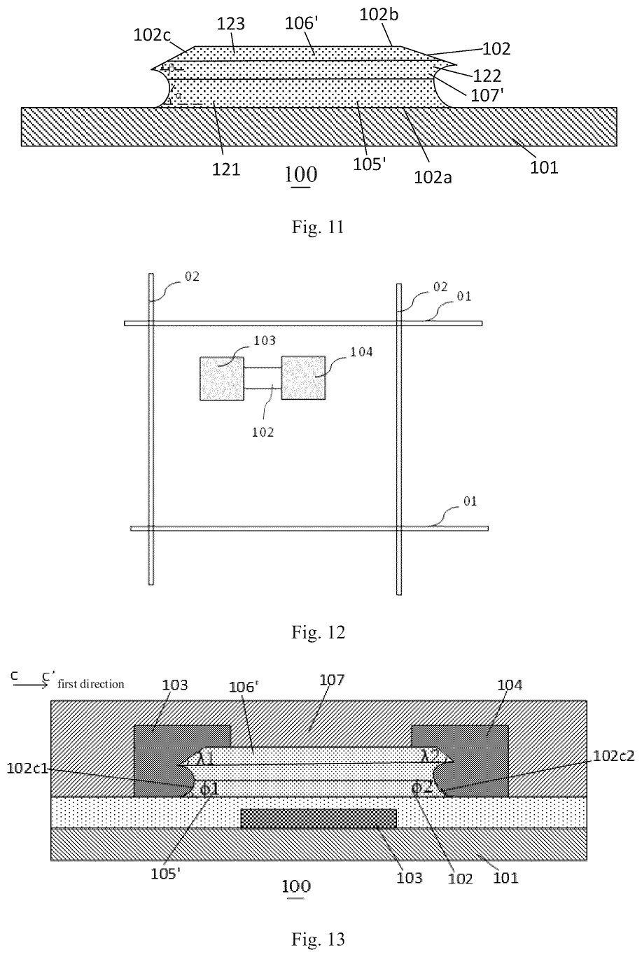

For example, FIG. 11 is a schematic cross-sectional structure diagram of another metal oxide thin film transistor provided by at least one embodiment of the present disclosure. As illustrated by FIG. 10, the metal oxide semiconductor layer 102 includes an amorphous layer or a nano-crystalline layer 121, a crystalline layer 123, and a transition layer 122 with a crystalline state between amorphous state and crystalline state, and the transition layer 122 is located between the amorphous layer or the nano-crystalline layer 121 and the crystalline layer 123 in the thickness direction of the metal oxide semiconductor layer 102. The outer contour of the concave surface is a ½ elliptical are, which may not be a strict ½ elliptical arc, but may be any similar curved shape with a semi-elliptical shape, for example, a shape close to a semi-circular are, a semi-water drop, etc. The outer contour of the side 102e corresponding to the edge of the transition layer 122 and the amorphous layer or the nano-crystalline layer 121 is a combination of a ½ arc and a straight line B-B′ passing through one end point thereof, and the straight line B-B′ extends to the transition layer 122.

For example, in one example, the concave surface is crescent-shaped, which belongs to the ½ arc, and can also be called as a bow shape.

For example, as illustrated by FIG. 11, the outer contour of the edge of the lateral surface 102c corresponding to the region of the crystalline layer 123 is a straight line perpendicular to the main surface of the base substrate 101, that is, the slope angle of the edge of the lateral surface 102c of the crystalline layer 123 is a right angle, and upon the crystalline layer 123 being etched, a uniform etching speed can be maintained.

For example, as illustrated by FIG. 11, an edge of the lateral surface 102c corresponding to the region where the crystalline layer 123 and the transition layer 122 abut has a convex corner protruding away from the center of the transition layer 122. For example, in FIG. 10, the convex corner is formed in the region corresponding to the edge of the transition layer 122. It should be noted that the convex corner may also be formed in the region corresponding to the adjacent portion of the transition layer 122 and the crystalline layer 123.

For example, as illustrated by FIG. 11. a region of the lateral surface 102ccorresponding to the crystalline layer 123 has a second angle , which is an average value. A region of the lateral surface 102c corresponding to the amorphous layer or the nano-crystalline layer 121 and the transition layer 122 has a first angle α. In the first angle α formed along the tangent of the outer edge of the concave surface, the first angle α first increases and then decreases along the direction from the lower surface 102a to the upper surface 102b, so as to form a concave surface that is concave toward the center of the metal oxide semiconductor layer 102.

For example, in one example, the first semiconductor layer 105′ is a nano-crystalline metal oxide semiconductor layer, the second semiconductor layer 106′ is a C-axis crystalline metal oxide semiconductor layer, the thickness of the second semiconductor layer 106′ is the largest, and the thickness of the third semiconductor region 107′ is the smallest.

For example, in one example, the metal oxide semiconductor layer 102 includes indium element, gallium element and zinc element, and in the metal oxide semiconductor layer 102, the element distribution in at least some regions satisfies that the molar ratio of zinc element to indium element is greater than 3:4, and the molar ratio of zinc element to gallium element is greater than 3:2.

For example, in one example, the material of the metal oxide semiconductor layer 102 includes indium gallium zinc oxide (IGZO). For example, after depositing the indium gallium zinc oxide film (IGZO-B) in the low oxygen environment of the chamber, the equipment has a pressure-stabilizing time of 20 seconds with the atmosphere changing, and the pressure-stabilizing atmosphere is 100% oxygen. In the oxygen enriched state, the target surface and the glass surface absorb more oxygen, and zinc element is easier to combine with oxygen, resulting in the interface layer is rich in zinc, and the content of the indium element in the interface layer is relatively small. In the metal oxide semiconductor layer formed by IGZO, the indium element is responsible for providing carrier channel, the gallium element has high ionization energy to inhibit electron mobility, and the zinc element can combine with strong chemical bonds of oxygen ions to form a stable tetrahedral structure.

It should be noted that although the metal oxide semiconductor layer 102 described in the embodiment of the present disclosure includes an amorphous layer or a nano-crystalline layer 121, a transition layer 122 and a crystalline layer 123.

In the direction perpendicular to the base substrate, the crystallinity of the metal semiconductor layer 102 is smaller in the region closer to the channel, the crystallinity of the channel region is the smallest, and the crystallinity of the region away from the channel region which protects the channel is higher. For example, in a bottom gate TFT, there is a semiconductor protection layer close to the gate insulating layer or close to the source electrode and the drain electrode, and the crystallinity of the semiconductor protection layer is higher than that of the channel region. Film layers with different crystallinity can be distinguished by density or crystallinity.

The metal oxide corresponding to the amorphous layer or the nano-crystalline layer 121 is not entirely composed of amorphous metal oxide, but may also include partial crystalline metal oxide. The metal oxides corresponding to the crystalline layer 123 are not all composed of crystalline metal oxides, but may also include some amorphous metal oxides. The crystalline state of the transition layer 122 is not completely between amorphous and crystalline, and may also include partially crystalline metal oxide and/or partially amorphous metal oxide, which is not limited by the embodiments of the present disclosure.

For example, although the boundaries between the amorphous layer or the nano-crystalline layer 121 and the transition layer 122, the transition layer 122 and the crystalline layer 123 are shown by straight lines in FIG. 11, they do not refer to the strict boundaries between the amorphous layer or the nano-crystalline layer 121, the transition layer 122 and the crystalline layer 123, the boundary between the amorphous layer or the nano-crystalline layer 121 and the transition layer 122, the boundary between the transition layer 122 and the crystalline layer 123 can also be curved lines or broken lines, and the embodiments of the present disclosure are not limited thereto.

For example, the molar ratio of indium element in the amorphous layer or the nano-crystalline layer 121 to indium element in the crystalline layer is 0.97 to 1.38, such as 1 to 1.12, 1.12 to 1.24 and 1.24 to 1.38; and the molar ratio of the indium element in the amorphous layer or the nano-crystalline layer 121 to the indium element in the transition layer 122 is 1.36 to 1.64, for example, 1.38 to 1.42, 1.42 to 1.53 and 1.53 to 1.64.

For example, the molar ratio of gallium element in the amorphous layer or the nano-crystalline layer 121 to gallium element in the crystalline layer 123 is 0.57 to 0.92, such as 0.59 to 0.68, 0.68 to 0.73, and 0.74 to 0.88; and the molar ratio of gallium element in the amorphous layer or the nano-crystalline layer 121 to gallium element in the transition layer 122 is 0.5 to 1.1, for example, 0.55 to 0.74, 0.82 to 0.94, 0.98 to 1.1.

For example, the molar ratio of zinc element in the amorphous layer or nano-crystalline layer 121 to zinc element in the crystalline layer 123 is 0.8 to 0.96, for example, 0.82 to 0.96; and the molar ratio of zinc element in the amorphous layer or the nano-crystalline layer 121 to zinc element in the transition layer 122 is 0.74 to 0.83, for example, 0.75 to 0.79 and 0.81 to 0.83.

For example, in the metal oxide semiconductor layer 102, the thickness of the amorphous layer or the nano-crystalline layer 121 is 50 angstroms to 200 angstroms, for example, 50 angstroms to 100 angstroms, 100 angstroms to 150 angstroms, and 180 angstroms to 200 angstroms. The thickness of the crystalline layer 123 is 80 angstroms to 400 angstroms, for example, 100 angstroms to 120 angstroms, 120 angstroms to 180 angstroms, and 220 angstroms to 400 angstroms. The thickness ratio of the crystalline layer 123 to the amorphous layer or the nano-crystalline layer 121 is 0.2 to 5, for example, 0.4 to 1 and 1.2 to 2.

For example, as illustrated by FIG. 11, the transition layer 122 is retracted to the central region of the metal oxide semiconductor layer 102 relative to the crystalline layer 123, that is, each lateral surface of the transition layer 122 is retracted to the central region of the metal oxide semiconductor layer 102 relative to the crystalline layer 123, and the outermost edge of the transition layer 122 and the outermost edge of the crystalline layer 123 are not aligned on each lateral surface, so that the length of the transition layer 122 is shorter than that of the crystalline layer 123.

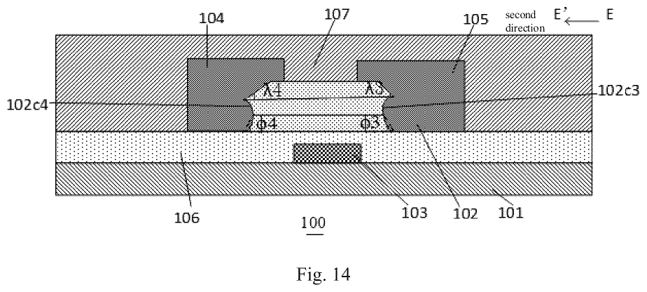

For example, FIG. 12 is a schematic plan structure of a pixel unit provided by at least one embodiment of the present disclosure. As illustrated by FIG. 12, a gate line 01 and a data line 02 intersect to define a pixel region A, and the metal oxide thin film transistor is arranged in the pixel region A, and the metal oxide thin film transistor is arranged in the vicinity of the intersection of the gate line 01 and the data line 02. The first direction C-C′ is from the position where the gate electrode is connected to the gate line 01 to a direction away from the metal oxide thin film transistor, and the second direction E-E′ is from the position where the drain electrode 104 is connected to the data line 02 to a direction away from the metal oxide thin film transistor 100. For example, FIG. 13 is a schematic cross-sectional view of the metal oxide thin film transistor in the structure shown in FIG. 12 cut along a line parallel to the first direction C-C′, and FIG. 14 is a schematic cross-sectional view of the metal oxide thin film transistor in the structure shown in FIG. 12 cut along a line parallel to the second direction E-E′. Referring to FIG. 12, FIG. 13 and FIG. 14, the metal oxide thin film transistor 100 includes the source electrode 103, the drain electrode 104 and the gate electrode (the gate line) 01. The data line 02 is connected to the drain electrode 104.

For example, as illustrated by FIG. 12, Figs. IA to 1F, and FIG. 13, in one pixel region A, the metal oxide semiconductor layer 102 extends along an extension direction of the gate line 01 and an extension direction of the data line 02. The gate line 01 and the data line 02 extend along the row direction and the column direction of the pixel array, respectively. The contour of the metal semiconductor layer 102 has four edges, and the lateral surface 102c includes a first lateral surface 102c1, a second lateral surface 102c2, a third lateral surface 102c3, and a fourth lateral surface 102c4 corresponding to the four edges. The first lateral surface 102c1 and the second lateral surface 102c2 are oppositely arranged, and the third lateral surface 102c3 and the fourth lateral surface 102c4 are oppositely arranged. The first lateral surface 102c1, the third lateral surface 102c3, the second lateral surface 102c2 and the fourth lateral surface 102c4 are sequentially arranged.

At least one of the first lateral surface, the third lateral surface, the second lateral surface and the fourth lateral surface satisfies a shape provided in the following:

The shape includes a third angle formed between a lateral surface of the first semiconductor layer of the metal oxide semiconductor layer and the lower surface; and a fourth angle formed between a lateral surface of the second semiconductor layer of the metal oxide semiconductor layer and the lower surface.

In one embodiment, the stacked metal oxide semiconductor has a double-layer structure including a first semiconductor layer 105′ and a second semiconductor layer 106′. Each of the first lateral surface 102c1. the third lateral surface 102c3, the second lateral surface 102c2, and the fourth lateral surface 102c4 includes a first semiconductor layer 105′ and a second semiconductor layer 106′ in turn in a direction extending from the edge close to the lower surface 102a to the edge close to the upper surface 102b, and there is a corner between the first semiconductor layer 105′ and the second semiconductor layer 106′. The included angle between at least partial region of the first semiconductor layer 105′ and a flat surface parallel to at least a part of the lower surface 102a and intersecting with the first semiconductor layer 105′ is the third angle ϕ (ϕ1, ϕ2); the included angle between at least a part of the second semiconductor layer 106′ and a flat surface parallel to at least a part of the lower surface 102a and intersecting with the second semiconductor layer 106′ is the fourth angle λ (λ1, λ2).

One embodiment is that the stacked metal oxide semiconductor has three layers, that is, there is a protective layer or a buffer layer between the channel layer and the gate insulating layer. Then, each of the first lateral surface 102e1, the third lateral surface 102c3. the second lateral surface 102c2 and the fourth lateral surface 102c4 includes a first semiconductor layer 105′ and a second semiconductor layer 106′ in the direction extending from the edge close to the channel region to the edge close to the upper surface 102b.

For example, as illustrated by FIGS. 12, 13 and 14, the source electrode 103 is connected to the common electrode line 03, and the length direction of the metal oxide semiconductor layer 102 is parallel to the extension direction of the gate line 01, that is, the length direction of the metal oxide semiconductor layer 102 is parallel to the first direction C-C′, and the width direction of the metal oxide semiconductor layer 102 is parallel to the extension direction of the data line 02, that is, the width direction of the metal oxide semiconductor layer 102 is parallel to the second direction E.

For example, the fourth angle λ1 of the first lateral surface 102c1 is smaller than the fourth angle λ2 of the second lateral surface 102c2; and/or, the fourth angle λ3 of the third lateral surface 102c3 is larger than the fourth angle λ4 of the fourth lateral surface 102c4; and/or the fourth angle λ2 of the second lateral surface 102c2 is larger than the fourth angle λ3 of the third lateral surface 102c3.

For example, upon the lateral surface 102c and the upper surface 102b of the metal oxide semiconductor layer 102 being etched and in contact with the etching solution, the geometric center of the metal oxide semiconductor layer 102 retracts inward, and the second lateral surface 102c2 retracts inward by less than the first lateral surface 102c1; and the third lateral surface 102c3 is retracted by a distance smaller than that of the fourth lateral surface 102c4.

For example, in one example, the slope angle of the curved surface on the first lateral surface 102c1 is smaller than the slope angle of the curved surface on the second lateral surface 102c2 in the region of the curved surface of the metal oxide semiconductor layer 102 which is at the same position from the base substrate 101 and close to the base substrate 101; and/or the slope angle of the curved surface on the fourth lateral surface 102c4 is smaller than the slope angle of the curved surface on the third lateral surface 102c3 in the region of the curved surface of the metal oxide semiconductor layer 102 which is at the same position from the base substrate 101 and close to the base substrate 101; and/or the slope angle of the curved surface on the second lateral surface 102c2 is the largest and the slope angle of the curved surface on the fourth lateral surface 102c4 is the smallest in the region of the curved surface of the metal oxide semiconductor layer 102 which is at the same position from the base substrate 101 and close to the base substrate 101.

For example, referring to FIGS. 13 and 14, the third angle ϕ2 of the second lateral surface 102c2 is larger than the third angle ϕ3 of the third lateral surface 102c3, and the curvature of the second curve is larger than the curvature of the third curve, that is, the bending degree of the second curve corresponding to the concave surface in the second lateral surface 102c2 is larger than the curvature of the third curve corresponding to the concave surface in the third lateral surface 102c3.

For example, as illustrated by conjunction with FIGS. 12, 13 and 14, in the second semiconductor layer 106′, the fourth angle λ1 in the first lateral surface 102c1 is smaller than the fourth angle λ2 in the second lateral surface 102c2.

For example, as illustrated by conjunction with FIGS. 12, 13 and 14, in the second semiconductor layer 106′, the fourth angle λ3 of the third lateral surface 102c3 is larger than the fourth angle λ4 of the fourth lateral surface 102c4.

For example, as illustrated by conjunction with FIGS. 12, 13 and 14, in the second semiconductor layer 106′, the fourth angle λ2 of the second lateral surface 102c2 is larger than the fourth angle λ3 of the third lateral surface.

For example, as illustrated by FIGS. 12, 13 and 14, the first lateral surface 102c1 includes a first type of concave surface, the second lateral surface 102c2 includes a second type of concave surface, the third lateral surface 102c3 includes a third type of concave surface, and the fourth lateral surface 102c4 includes a fourth type of concave surface. The first type of concave surface, the second type of concave surface, the third type of concave surface, and the fourth type of concave surface form third angles o with the lower surface 102a at positions having the same distance to the lower surface 102a.

For example, as illustrated by FIGS. 12, 13 and 14, the third angle ϕ1 on the first type of concave surface is smaller than the third angle ϕ2 on the second type of concave surface.

For example, as illustrated by FIGS. 12, 13 and 14, the third angle ϕ4 on the fourth type concave surface is smaller than the third angle ϕ3 on the third type concave surface.

For example, as illustrated by FIG. 12, FIG. 13 and FIG. 14, among the third angles ϕ1 of the first type concave surface, the third angles ϕ2 of the second type concave surface, the third angles ϕ3 of the third type concave surface, the third angles ϕ4 of the fourth type concave surface, the third angles ϕ2 of the second type concave surface is the largest and the third angles ϕ4 of the fourth type concave surface is the smallest.

For example, as illustrated by FIGS. 12, 13 and 14, the first contact region 105 and the second contact region 106 are located on the third lateral surface 102c3 or the fourth lateral surface 102c4.

For example, as illustrated by FIG. 12, FIG. 13 and FIG. 14, the metal oxide thin film transistor 100 is a switching transistor in a pixel display region. The metal oxide thin film transistor 100 is arranged in a pixel region A defined by the gate line 01 and the data line 02 which intersect with each other, the gate line 01 and the data line 02 extend in the row direction and the column direction of the pixel array, respectively. The metal oxide semiconductor layer 102 extends in the direction of the gate line 01, and the first contact region 105 and the second contact region 106 are located at two end portions of the metal oxide semiconductor layer 102 in the extension direction thereof respectively.

For example, as illustrated by FIG. 13, the first lateral surface 102c1 and the second lateral surface 102c2 are also arranged along the length direction of the metal oxide semiconductor layer 102, and the third angle ϕ1 of the first lateral surface 102c1 is smaller than the third angle ϕ2 of the second lateral surface 102c2, that is, the inclination degree of the first lateral surface 102c1 is smaller than the inclination degree of the second lateral surface 102c2.

In some embodiments, among the third angle on the first lateral surface, the third angle on the second lateral surface, the third angle on the third lateral surface and the third angle on the fourth lateral surface, the third angle on the second lateral surface is the largest and the third angle on the fourth lateral surface is the smallest.

For example, as illustrated by FIG. 13, taking the case that the lateral surfaces of the first lateral surface 102c1 and the second lateral surface 102c2 corresponding to the middle area in the thickness direction of the metal oxide semiconductor layer 102 are concave surfaces with the outer contours of ½ circular ares respectively as an example, and the outer contour of the concave surface corresponding to the first lateral surface 102c1 is the first curve. The outer contour of the concave surface corresponding to the second lateral surface 102c2 is a second curve, and the curvature of the first curve is smaller than the curvature of the second curve, that is, the bending degree of the second curve corresponding to the concave surface in the second lateral surface 102c2 is greater than that of the first curve corresponding to the concave surface in the first lateral surface 102c1.

For example, as illustrated by FIG. 13, the second semiconductor layer 106′ of the lateral surface 102c includes a slope with a fourth angle λ (λ1, λ2), which is a constant value; the first semiconductor layer 105′ of the lateral surface 102c has a third angle ϕ (ϕ1, ϕ2), which includes a series of continuously changing angles. From a side close to the base substrate 101 to a side away from the base substrate 101, a series of continuously changing third angles first increase and then decrease; and the curvature centers of the curved surfaces with the third angles increasing first and then decreasing are located on the same side.

For example, during the patterning process of the metal oxide semiconductor layer 102, the first direction C-C′ is the advancing direction of the base substrate 101, that is, the second lateral surface 102c2 receives the etching solution first and is etched first, and the first lateral surface 102c1 receives the etching solution later and is etched later relative to the second lateral surface 102c2, so that the third angle ϕ1 of the first lateral surface 102c1 is smaller than the third angle ϕ2 of the second lateral surface 102c2. And the bending degree of the second curve corresponding to the concave surface in the second lateral surface 102c2 is greater than that of the first curve corresponding to the concave surface in the first lateral surface 102c1.

For example, as illustrated by FIG. 14, the third angle ϕ3 of the third lateral surface 102c3 is larger than the third angle ϕ4 of the fourth lateral surface 12c4. The outer contour of the concave surface corresponding to the third lateral surface 12c3 is a third curve, and the outer contour of the concave surface corresponding to the fourth lateral surface 12c4 is a fourth curve. The curvature of the third curve is larger than that of the fourth curve, that is, the bending degree of the third curve corresponding to the concave surface in the third lateral surface 12c3 is larger than that of the fourth curve corresponding to the concave surface in the fourth lateral surface 12c4.

For example, during the patterning process of the metal oxide semiconductor layer 102, the base substrate 101 is placed obliquely at a certain angle with the horizontal flat surface, for example, 2 degrees to 10 degrees, so that the position of the third lateral surface 102c3 is higher than that of the fourth lateral surface 102c4, and the third lateral surface 102c3 receives the etching solution first and is etched first. The fourth lateral surface 102c4 receives the etching solution later and is etched later relative to the third lateral surface 102c3, so that the third angle ϕ3 of the third lateral surface 102c3 is larger than the third angle ϕ4 of the fourth lateral surface 102c4, and the bending degree of the third curve corresponding to the concave surface in the third lateral surface 102c3 is larger than that of the fourth curve corresponding to the concave surface in the fourth lateral surface 102c4.

For example, upon the lateral surface 102c and the upper surface 102b of the metal oxide semiconductor layer 102 being in contact with the etching solution and being etched, the geometric center of the metal oxide semiconductor layer 102 retracts inward, and the geometric center of the second lateral surface 102c2 retracts by less than the geometric center of the first lateral surface 102c1; the geometric center of the third lateral surface 102c3 is retracted by a distance smaller than that of the fourth lateral surface 102c4.

For example, in FIGS. 13 and 14, the metal oxide thin film transistor 100 is illustrated as a bottom gate thin film transistor, but the embodiment of the present disclosure is not limited thereto, and the metal oxide thin film transistor 100 can also be a top gate thin film transistor or a double gate thin film transistor according to product requirements.

For example, in FIGS. 13 and 14, the gate electrode 103 is arranged between the base substrate 101 and the metal oxide semiconductor layer 102, and the material of the gate electrode 103 may be a combination of copper and other metals, such as copper/molybdenum (Cu/Mo), copper/titanium (Cu/Ti), copper/molybdenum titanium alloy (Cu/MoTi), copper/molybdenum tungsten alloy (Cu/MoW), and copper/molybdenum niobium alloy (Cu/MoNb). The material of the gate electrode 103 can also be a chromium-based metal or a combination of chromium and other metals, such as chromium/molybdenum (Cr/Mo), chromium/titanium (Cr/Ti) or chromium/molybdenum titanium alloy (Cr/MoTi).

For example, as illustrated by FIGS. 13 and 14, a gate insulating layer 106 is further provided between the gate electrode 103 and the metal oxide semiconductor layer 102. The material of the gate insulating layer 106 includes at least one of the insulating oxides, such as silicon oxide (SiO₂), aluminum oxide (Al₂O₃), silicon nitride (SiN), titanium oxide (TiO₂), hafnium oxide (HfO₂), tantalum oxide (Ta₂O₅) and zirconium oxide (ZrO₂).

For example, as illustrated by FIGS. 13 and 14, a source electrode 104 and a drain electrode 105 are further arranged on a side of the metal oxide semiconductor layer 102 away from the base substrate 101, and the materials of the source electrode 104 and the drain electrode 105 may include one or a combination of more metals such as molybdenum (Mo), chromium (Cr), titanium (Ti), aluminum (Al), aluminum alloy and copper (Cu).

For example, in one example, the material of the source electrode 104 and the drain electrode 105 is copper-based metal. Copper has the characteristics of low resistivity and good conductivity, so it can improve the signal transmission rate of the source electrode 104 and the drain electrode 105, so as to improve the display quality. For example, the copper-based metal is copper (Cu), copper zinc alloy (CuZn), copper nickel alloy (CuNi) or copper zinc nickel alloy (CuZnNi) with stable performance.

For example, as illustrated by FIGS. 13 and 14, a passivation layer 107 is further provided at a side of the source electrode 104 and the drain electrode 105 away from the base substrate 101. The material of the passivation layer 107 is an inorganic insulating material. For example, the inorganic insulating material is at least one of the insulating oxides, such as silicon oxide (SiO₂), aluminum oxide (Al₂O₃), silicon nitride (SiN), titanium oxide (TiO₂) and hafnium oxide (HfO₂), tantalum oxide (Ta₂O₅) and zirconium oxide (ZrO₂).

For example, other structures of the metal oxide thin film transistor can be referred to the conventional designs, and the embodiments of the present disclosure will not be described in detail.

At least one embodiment of the present disclosure further provides a display panel including the metal oxide thin film transistor described in any one of the embodiments mentioned above. The characteristics of the display panel can refer to the characteristics of a conventional display panel, and the embodiments of the present disclosure are not limited thereto.

The metal oxide thin film transistor and the display panel provided by at least

one embodiment of the present disclosure have the following technical effects:
(1) The metal oxide thin film transistor provided by at least one embodiment of the present disclosure can ensure that the width of the channel region of the metal oxide thin film transistor is as large as possible, the mobility of the carriers is as high as possible, and the characteristics of the metal oxide thin film transistor are as stable as possible, so as to improve the characteristics and the yield of the metal oxide thin film transistor.
(2) According to the metal oxide thin film transistor provided by at least one embodiment of the present disclosure, the shape of the lateral surface of the metal oxide semiconductor layer in the metal oxide thin film transistor is made into a concave shape by controlling the process conditions, that is, the risk of peeling of the adjacent layers of the metal oxide thin film transistor can be reduced, so that the adhesion between the metal oxide semiconductor layer in the metal oxide thin film transistor and its adjacent film layer is stronger. and the characteristics and the yield of the metal oxide thin film transistor can be improved.

The following points need to be explained:
(1) The drawings of the embodiments of the present disclosure only refer to the structures related to the embodiments of the present disclosure, and other structures can refer to the general design.
(2) For the sake of clarity, in the drawings used to describe the embodiments of the present disclosure, the thicknesses of layers or regions are enlarged or reduced, that is, these drawings are not drawn to actual scale. It can be understood that when an element such as a layer, a film, a region or a substrate is said to be located “above” or “below” another element, the element may be located “directly” “above” or “below” another element, or there may be intervening elements.
(3) Without conflict, the embodiments of the present disclosure and the features in the embodiments can be combined with each other to obtain a new embodiment.

The above is only an exemplary embodiment of the present disclosure, and it is not intended to limit the scope of protection of the present disclosure, which is determined by the appended claims.

1. A metal oxide thin film transistor, comprising:
a metal oxide semiconductor layer on a base substrate, and a source electrode and a drain electrode being in contact with the metal oxide semiconductor layer;
wherein the metal oxide semiconductor layer comprises a stacked structure, the stacked structure at least comprises a first semiconductor layer and a second semiconductor layer, a carrier mobility of the first semiconductor layer is higher than a carrier mobility of the second semiconductor layer;
the metal oxide semiconductor layer comprises a lower surface, an upper surface and a lateral surface, and the source electrode is in contact with the lateral surface and the upper surface; a region of the lateral surface being in contact with the source electrode or the drain electrode at least comprises a first contact region located on the first semiconductor layer and a second contact region located on the second semiconductor layer;
the first contact region and the second contact region on the oxide semiconductor layer comprise a shape provided in the following: the shape comprises a first angle between the lower surface of the metal oxide semiconductor layer and the lateral surface of the first contact region, and a second angle between the lower surface of the metal oxide semiconductor layer and the lateral surface of the second contact region, and the first angle is larger than the second angle.

2. The metal oxide thin film transistor according to claim 1, wherein the first angle is an included angle between the first contact region and a flat surface parallel to the lower surface and intersecting with the first contact region; and
the second angle is an included angle between the second contact region and a flat surface parallel to the lower surface and intersecting with the second contact region.

3. The metal oxide thin film transistor according to claim 1, wherein the second semiconductor layer is close to the source electrode and the drain electrode in the stacked structure of the metal oxide semiconductor layer;
the first contact region is all or part of a contact region between the source electrode or the drain electrode and the first semiconductor layer, and the second contact region is all or part of a contact region between the source electrode or the drain electrode and the second semiconductor layer.

4. The metal oxide thin film transistor according to claim 1, wherein the first semiconductor layer and the second semiconductor layer satisfy at least one of the following conditions:
the first semiconductor layer and the second semiconductor layer comprise metal oxide semiconductors with different crystallinity;
the first semiconductor layer and the second semiconductor layer comprise metal oxide semiconductors with different compositions;
the first semiconductor layer and the second semiconductor layer comprise metal oxide semiconductors with different band gaps.

5. The metal oxide thin film transistor according to claim 3, wherein a crystallinity of the metal oxide of the first semiconductor layer is smaller than a crystallinity of the metal oxide of the second semiconductor layer.

6. The metal oxide thin film transistor according to claim 1, wherein in a direction perpendicular to a main surface of the base substrate, an extension distance of the first contact region from a position closest to the upper surface to a position closest to the lower surface is smaller than an extension distance of the second contact region from a position closest to the upper surface to a position closest to the lower surface.

7. The metal oxide thin film transistor according to claim 1, wherein a width of an projection contour of the first contact region on the base substrate is L1, a width of an projection contour of the second contact region on the base substrate is L2, and L1 is less than L2.

8-9. (canceled)

10. The metal oxide thin film transistor according to claim 1, wherein the metal oxide semiconductor layer further comprises a third semiconductor layer;
the third semiconductor layer is located between the first semiconductor layer and the second semiconductor layer and is in direct contact with the first semiconductor layer and the second semiconductor layer.

11. The metal oxide thin film transistor according to claim 10, wherein a crystallinity of at least a part of the metal oxide semiconductor layer satisfies:
a crystallinity of the metal oxide of the third semiconductor layer is larger than a crystallinity of the metal oxide of the first semiconductor layer and smaller than a crystallinity of the metal oxide of the second semiconductor layer.

12. (canceled)

13. The metal oxide thin film transistor according to claim 1, wherein the metal oxide semiconductor layer comprises an overlapping region that at least partially overlaps with a projection of the source electrode or the drain electrode on the base substrate, and a non-overlapping region that does not overlap with the projection of the source electrode or the drain electrode on the base substrate;
a content percentage of oxygen (O) element of the overlapping region is smaller than a content percentage of oxygen element of the non-overlapping region.

14-21. (canceled)

22. The metal oxide thin film transistor according to claim 1, wherein the first contact region is a first concave surface, and at least a part of the first concave surface is located in the first semiconductor layer.

23. The metal oxide thin film transistor according to claim 22, wherein in a direction of the first concave surface away from the lower surface, the first angle first increases and then decreases, and a distance between the first concave surface and a center of the metal oxide semiconductor layer first decreases and then increases.

24. (canceled)

25. The metal oxide thin film transistor according to claim 22, wherein
the first contact region is the first concave surface, and values of the first angles between different positions of the first contact region and the lower surface are the same value or a plurality of different values;
the second contact region is a smooth second flat surface, and second angles between different positions of the second contact region and a flat surface parallel to at least a part of the lower surface and intersecting with the second contact region have the same value or a plurality of different values.

26. The metal oxide thin film transistor according to claim 25, wherein a corner is formed between the first contact region and the second contact region, and an included angle between two surfaces corresponding to the corner is an obtuse angle.

27. The metal oxide thin film transistor according to claim 1, wherein a contour of the metal oxide semiconductor layer comprises four edges, and the four edges correspond to a first lateral surface, a second lateral surface, a third lateral surface and a fourth lateral surface respectively, and the first lateral surface and the second lateral surface are oppositely arranged, the third lateral surface and the fourth lateral surface are oppositely arranged;
the first lateral surface, the third lateral surface, the second lateral surface and the fourth lateral surface are sequentially arranged;
the first contact region is a region where the source electrode is in contact with at least one of the second lateral surface and the third lateral surface.

28. The metal oxide thin film transistor according to claim 27, wherein at least one of the first lateral surface, the third lateral surface, the second lateral surface and the fourth lateral surface satisfies a shape provided in the following:
the shape comprises a third angle formed between the lateral surface and the lower surface of the first semiconductor layer of the metal oxide semiconductor layer and a fourth angle formed between the lateral surface and the lower surface of the second semiconductor layer of the metal oxide semiconductor layer.

29-33. (canceled)

34. The metal oxide thin film transistor according to claim 28, wherein among the third angle on the first lateral surface, the third angle on the second lateral surface, the third angle on the third lateral surface and the third angle on the fourth lateral surface, the third angle on the second lateral surface is the largest and the third angle on the fourth lateral surface is the smallest.

35. The metal oxide thin film transistor according to claim 28, wherein the metal oxide thin film transistor is a switching transistor of a pixel display region, and the metal oxide thin film transistor is arranged in a pixel region defined by a gate line and a data line which intersect with each other, the gate line and the data line respectively extend along a row direction and a column direction of a pixel array, and a channel length direction of the metal oxide semiconductor layer extends along a direction of the gate line.

36. The metal oxide thin film transistor according to claim 3, wherein the first semiconductor layer comprises an amorphous or nano-crystalline metal oxide semiconductor; and the second semiconductor layer comprises a c- axis crystallized metal oxide semiconductor.

37-42. (canceled)

43. A display panel, comprising the metal oxide thin film transistor according to claim 1.
